(19) United States
(12) Patent Application Publication
(10) Pub. No.: US 2020/0223215 A1
(43) Pub. Date: Jul. 16, 2020

(54) PRINTING PLATE PRECURSOR, METHOD OF PRODUCING PRINTING PLATE, AND PRINTING METHOD

(71) Applicant: FUJIFILM Corporation, Tokyo (JP)

(72) Inventor: Shuji SHIMANAKA, Shizuoka (JP)

(73) Assignee: FUJIFILM Corporation, Tokyo (JP)

(21) Appl. No.: 16/828,969

(22) Filed: Mar. 25, 2020

Related U.S. Application Data
(63) Continuation of application No. PCT/JP2018/020511, filed on May 29, 2018.

(30) Foreign Application Priority Data
Sep. 29, 2017 (JP) 2017-189962

(51) Int. Cl. B41C 1/10; B41F 1/16; G03F 7/09; G03F 7/033

(52) U.S. Cl. CPC B41C 1/1008; G03F 7/033; G03F 7/09; B41F 1/16

(57) ABSTRACT

The present invention provides a printing plate precursor, a method of producing a printing plate, and a printing method with excellent stain resistance and deinking capability after being left to stand at the time of obtaining a printing plate. The printing plate precursor of the present invention is a printing plate precursor including an aluminum support, and a functional layer which is disposed on the aluminum support, in which the aluminum support includes an aluminum plate and an aluminum anodized film disposed on the aluminum plate, the anodized film is positioned closer to the functional layer than the aluminum plate is, the anodized film has micropores extending in a depth direction from a surface of the functional layer side, and an average diameter of the micropores in the surface of the anodized film is in a range of 13 nm to 100 nm, the printing plate precursor contains a hydrophilizing agent in a region on a plate surface of the functional layer side which extends to a distance of 5 mm inward from two facing end portions of the printing plate precursor, and a content of the hydrophilizing agent per unit area in the region is greater than a content of the hydrophilizing agent per unit area in a region other than the region by 10 mg/m² or greater.

### CROSS-REFERENCE TO RELATED APPLICATIONS

This application is a Continuation of PCT International Application No. PCT/JP2018/020511 filed on May 29, 2018, which claims priority under 35 U.S.C. § 119(a) to Japanese Patent Application No. 2017-189962 filed on Sep. 29, 2017. The above application is hereby expressly incorporated by reference, in its entirety, into the present application.

### BACKGROUND OF THE INVENTION

### 1. Field of the Invention

The present invention relates to a printing plate precursor, a method of producing a printing plate, and a printing method.

### 2. Description of the Related Art

In recent years, planographic printing plates are obtained using a computer-to-plate (CTP) technology, and accordingly various research has been conducted

For example, WO2015/119089A discloses a method of producing a planographic printing plate precursor using a coating solution that contains a hydrophilizing agent.

### SUMMARY OF THE INVENTION

WO2015/119089A describes that occurrence of linear stains (edge stains) due to transfer of an ink, adhering to an end portion of a printing plate, to paper can be prevented.

Meanwhile, in recent years, there is a demand for further improvement for edge stain resistance, but the aspect described in WO2015/119089A does not necessarily satisfy the demand.

Further, a printing plate is also required to have excellent deinking capability after being left to stand. Further, the expression “the deinking capability after being left to stand is excellent” means that printing paper is unlikely to be stained at the time of resuming printing after the printing is temporarily stopped and left to stand.

The present invention has been made in consideration of the above-described circumstances, and an object thereof is to provide a printing plate precursor with excellent edge stain resistance and excellent deinking capability after being left to stand, at the time of obtaining a printing plate.

Further, another object of the present invention is to provide a method of producing a printing plate and a printing method.

As the result of intensive research conducted by the present inventors in order to achieve the above-described object, it was found that the above-described object can be achieved by employing the following configurations.

(1) A printing plate precursor comprising: an aluminum support; and a functional layer which is disposed on the aluminum support and selected from the group consisting of an image recording layer and a non-photosensitive layer, in which the aluminum support includes an aluminum plate and an aluminum anodized film disposed on the aluminum plate, the anodized film is positioned closer to the functional layer than the aluminum plate is, the anodized film has micropores extending in a depth direction from a surface of the functional layer side, and an average diameter of the micropores in the surface of the anodized film is in a range of 13 nm to 100 nm, the printing plate precursor contains a hydrophilizing agent in a region on a plate surface of the functional layer side which extends to a distance of 5 mm inward from two facing end portions of the printing plate precursor, and a content of the hydrophilizing agent per unit area in the region is greater than a content of the hydrophilizing agent per unit area in a region other than the region by 10 mg/m² or greater.

(2) The printing plate precursor according to (1), in which the content of the hydrophilizing agent per unit area in the region is greater than the content of the hydrophilizing agent per unit area in a region other than the region by 10 to 2000 mg/m² or greater.

(3) The printing plate precursor according to (1) or (2), in which the end portion of the printing plate precursor has a sagging shape with a sagging amount of 25 to 150 μm and a sagging width of 70 to 300 μm.

(4) The printing plate precursor according to any one of (1) to (3), in which the average diameter of the micropores in the surface of the anodized film is in a range of 13 to 30 nm, and a maximum diameter inside the micropore is in a range of 40 to 300 nm.

(5) The printing plate precursor according to any one of (1) to (3), in which the micropores are formed of large-diameter pores extending to a position at a depth of 10 nm to 1000 nm from the surface of the anodized film and small-diameter pores communicating with a bottom of the large-diameter pores and extending to a position at a depth of 20 nm to 2000 nm from a communication position, an average diameter of the large-diameter pores in the surface of the anodized film is in a range of 15 nm to 100 nm, and an average diameter of the small-diameter pores in the communication position is 13 nm or less.

(6) The printing plate precursor according to any one of (1) to (5), in which the hydrophilizing agent is a water-soluble compound.

(7) The printing plate precursor according to any one of (1) to (6), in which the hydrophilizing agent contains at least one selected from the group consisting of a phosphoric acid compound and a phosphonic acid compound.

(8) The printing plate precursor according to (7), in which the phosphoric acid compound and the phosphonic acid compound are polymer compounds.

(9) The printing plate precursor according to any one of (1) to (8), in which the hydrophilizing agent contains a water-soluble resin.

(10) The printing plate precursor according to any one of (1) to (9), in which the hydrophilizing agent contains an anionic surfactant or a non-ionic surfactant.

(11) The printing plate precursor according to any one of (1) to (10), in which the functional layer is an image recording layer which contains an infrared absorbing agent, a polymerization initiator, a polymerizable compound, and a polymer compound.

(12) The printing plate precursor according to (11), in which the polymer compound contained in the image recording layer has a hydrophobic main chain and both a repeating unit which contains a pendant-cyano group directly bonded to the hydrophobic main chain and a repeating unit which contains a pendant group having a hydrophilic polyalkylene oxide segment.

(13) The printing plate precursor according to any one of (1) to (10), in which the functional layer is an image recording layer which contains an infrared absorbing agent and thermoplastic polymer particles.

(14) A method of producing a printing plate, comprising: an exposure step of imagewise-exposing the printing plate precursor according to any one of (11) to (13) to form an exposed portion and an unexposed portion; and a removal step of removing the unexposed portion of the imagewise-exposed printing plate precursor.

(15) A printing method comprising: an exposure step of imagewise-exposing the printing plate precursor according to any one of (11) to (13) to form an exposed portion and an unexposed portion; and a printing step of supplying at least any of printing ink or dampening water and removing the unexposed portion of the imagewise-exposed printing plate precursor on a printing press to perform printing.

According to the present invention, it is possible to provide a printing plate precursor with excellent edge stain resistance and excellent deinking capability after being left to stand, at the time of obtaining a printing plate.

Further, according to the present invention, it is also possible to provide a method of producing a printing plate and a printing method.

### BRIEF DESCRIPTION OF THE DRAWINGS

FIG. 1 is a schematic cross-sectional view illustrating an embodiment of a printing plate precursor according to an embodiment of the present invention.

FIG. 2 is a schematic cross-sectional view illustrating an embodiment of an aluminum support.

FIG. 3 is a schematic view illustrating an example of a cross-sectional shape of an end portion of the printing plate precursor according to the embodiment of the present invention.

FIG. 4 is a graph showing an example of an alternating waveform current waveform diagram used for an electrochemical roughening treatment according to a method of producing the aluminum support.

FIG. 5 is a side view illustrating an example of a radial type cell in the electrochemical roughening treatment carried out using the alternating current according to the method of producing the aluminum support.

FIG. 6 is a conceptual view illustrating an example of a cutting unit of a slitter device.

FIG. 7 is a schematic cross-sectional view illustrating another embodiment of an aluminum support.

FIG. 8 is a schematic view illustrating an anodization treatment device used for an anodization treatment in preparation of the aluminum support.

FIG. 9 is a side view illustrating the concept of a brush graining step used for a mechanical roughening treatment in preparation of the aluminum support.

### DESCRIPTION OF THE PREFERRED EMBODIMENTS

Hereinafter, a printing plate precursor according to the embodiment of the present invention will be described.

Further, in the present specification, the numerical ranges shown using “to” indicate ranges including the numerical values described before and after “to” as the lower limits and the upper limits.

Further, in the present specification, in a case where substitution or unsubstitution is not noted in regard to the notation of a group in a compound represented by a formula and the group may further have a substituent, the group includes not only an unsubstituted group but also a group having a substituent unless otherwise specified. For example, in a formula, the description of “R represents an alkyl group, an aryl group, or a heterocyclic group” means that “R represents an unsubstituted alkyl group, a substituted alkyl group, an unsubstituted aryl group, a substituted aryl group, an unsubstituted heterocyclic group, or a substituted heterocyclic group”.

As the characteristics of the printing plate precursor according to the embodiment of the present invention, the average diameter of micropores in a surface of an anodized film is in a range of 13 to 100 nm, and the printing plate precursor contains a predetermined amount of a hydrophilizing agent in a predetermined region. Particularly in a case where the average diameter of the micropores in the surface of the anodized film is in a range of 13 to 100 nm, it was found that the balance between the edge stain resistance and the deinking capability after being left to stand is excellent. Further, the specific reason why the edge stain resistance is improved by adjusting the average diameter thereof is not unclear, but it is assumed that cracks are unlikely to occur in an end portion of the printing plate precursor.

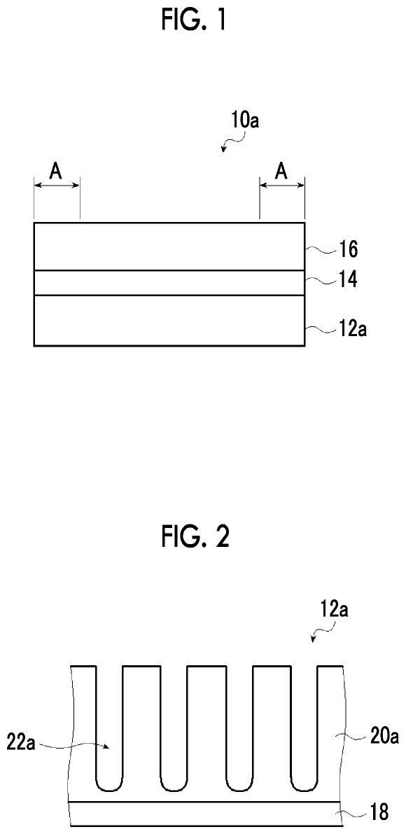

FIG. 1 is a schematic cross-sectional view illustrating an embodiment of the printing plate precursor according to the embodiment of the present invention.

A printing plate precursor 10a illustrated in the same figure includes an aluminum support 12a, an undercoat layer 14, and a functional layer 16.

FIG. 2 is a schematic cross-sectional view illustrating an embodiment of the aluminum support 12a. The aluminum support 12a has a laminated structure in which an aluminum plate 18 and an aluminum anodized film 20a (hereinafter, also simply referred to as an “anodized film 20a”) are laminated in this order. Further, the anodized film 20a in the aluminum support 12a is positioned closer to the functional layer 16 side than the aluminum plate 18 is. That is, the printing plate precursor 10a includes the aluminum plate 18, the anodized film 20a, the undercoat layer 14, and the functional layer 16 in this order.

The anodized film 20a has micropores 22a extending from the surface thereof to the aluminum plate 18 side. Further, the term “micropores” here is a general term used to indicate pores in the anodized film and does not specify the size of the pore.

As described in detail below, the undercoat layer 14 is not an indispensable component and is a layer to be disposed as necessary.

In the printing plate precursor according to the embodiment of the present invention, the content of the hydrophilizing agent in end portion regions is intentionally increased by the means for coating only two facing end portion regions of the printing plate precursor with the hydrophilizing agent as compared to a region other than the end portion region. Specifically, a content A of the hydrophilizing agent per unit area in the region on a plate surface of the functional layer side which extends to a distance of 5 mm inward from the end portions of the printing plate precursor is greater than a content B of the hydrophilizing agent per unit area in a region other than the region by 10 mg/m² or greater. In other words, a difference in the content of the hydrophilizing agent (content A−content B) is 10 mg/m² or greater.

From the viewpoint that at least one of the edge stain resistance or the deinking capability after being left to stand is further excellent (hereinafter, also simply referred to as “from the viewpoint that the effects of the present invention are further excellent”), the difference in the content of the hydrophilizing agent (content A−content B) is preferably 50 mg/m² or greater, more preferably 200 mg/m² or greater, and still more preferably 700 mg/m² or greater. The upper limit thereof is not particularly limited, but is preferably 5000 mg/m² or less and more preferably 3000 mg/m² or less, and still more preferably 2000 mg/m² or less from the viewpoint of further suppressing stains in a setter and a vender.

The end portion of the printing plate precursor indicates an edge portion formed by a step of cutting a plate in the form of a sheet in the process of producing the printing plate precursor. The sheet-like printing plate precursor has four end portions in the lateral direction and the longitudinal direction. In the printing plate precursor according to the embodiment of the present invention, at least two facing end portions may satisfy the above-described requirements. For example, typically, it is preferable that in a case of newspaper printing, two facing sides of the printing plate precursor along a roll paper transport direction in the plane of printing paper correspond to the end portions.

Further, the region of the plate surface on the functional layer side which extends to a distance of 5 mm inward from the end portions include not only the functional layer but also all layers provided on the functional layer side of the aluminum support. Accordingly, the content of the hydrophilizing agent per unit area in the region of the plate surface on the functional layer side which extends to a distance of 5 mm inward from the end portions indicates the total content of the hydrophilizing agent per unit area which is present in the region. Similarly, the content of the hydrophilizing agent per unit area in the region other than the region indicates the total content of the hydrophilizing agent per unit area which is present in the region.

That is, the amount of the hydrophilizing agent included in the region of the plate surface on the functional layer side which extends to a distance of 5 mm inward from the end portions of the printing plate precursor indicates the amount of the hydrophilizing agent in the upper portion of the aluminum support in the region extending to a distance of 5 mm inward from the end portions of the printing plate precursor. In FIG. 1, the amount of the hydrophilizing agent included in the region of the plate surface on the functional layer side which extends to a distance of 5 mm inward from the end portions of the printing plate precursor 10a indicates the amount of the hydrophilizing agent in the upper portion of the aluminum support 12a in a region A extending to a distance of 5 mm inward from the end portions of the printing plate precursor 10a. For example, in a case where the hydrophilizing agent is disposed between the aluminum support 12a and the undercoat layer 14 in the region A, the hydrophilizing agent corresponds to the hydrophilizing agent in the region A. Further, as another example, in a case where the hydrophilizing agent is disposed between the undercoat layer 14 and the functional layer 16 in the region A, the hydrophilizing agent corresponds to the hydrophilizing agent in the region A.

Further, according to a preferable embodiment of the printing plate precursor of the present invention, it is preferable that the layers are arranged in any of the following orders. As described in (5), (6), and (8) below, the layer containing the hydrophilizing agent may be provided on the outermost surface side of the printing plate precursor (the surface side on the opposite side of the aluminum support).

(1) An aluminum support, a layer containing a hydrophilizing agent, and a functional layer;

(2) An aluminum support, a layer containing a hydrophilizing agent, an undercoat layer, and a functional layer;

(3) An aluminum support, a layer containing a hydrophilizing agent, a functional layer, and a protective layer;

(4) An aluminum support, a layer containing a hydrophilizing agent, an undercoat layer, a functional layer, and a protective layer;

(5) An aluminum support, a functional layer, and a layer containing a hydrophilizing agent;

(6) An aluminum support, an undercoat layer, a functional layer, and a layer containing a hydrophilizing agent;

(7) An aluminum support, an undercoat layer, a functional layer, a layer containing a hydrophilizing agent, and a protective layer; and

(8) An aluminum support, an undercoat layer, a functional layer, a protective layer, and a layer containing a hydrophilizing agent

In the printing plate precursor according to the embodiment of the present invention, the region extending to a distance of 5 mm inward from the end portions is also referred to as an end portion region. Further, regions other than the end portion region are also referred to as other regions.

The content of the hydrophilizing agent per unit area in the end portion region and the other regions can be calculated according to a known method. For example, the content thereof can be obtained using a known device such as a scanning X-ray photoelectric spectrometer, a Fourier transform infrared absorption spectrum (FT-IR) measuring device, or a corona charged particle detector (Corona CAD, manufactured by Thermo Fisher Scientific Inc.).

For example, in a case where the hydrophilizing agent contains a phosphorus atom, a sample A is obtained by obliquely cutting the end portion region of the printing plate precursor at a width of 2 mm and an angle of 0.1°. Further, in other regions of the printing plate precursor, a sample B is obtained by obliquely cutting the printing plate precursor in the same manner as described above.

The content of the hydrophilizing agent per unit area in the obliquely cut surface of the sample A or the sample B can be acquired by quantifying a P—Ox bond and converting the obtained value per unit area (m²) in a visual field with a size of 0.5 mm×0.5 mm square using a scanning X-ray photoelectric spectrometer (PHI Quantera 2000, manufactured by ULVAC-PHI, Inc.).

For example, in a case where the hydrophilizing agent contains a sulfur atom, the content of the hydrophilizing agent per unit area can be determined by quantifying a S-Ox bond in the same manner as described above.

For example, in a case where the hydrophilizing agent is a surfactant (such as an anionic surfactant or a non-ionic surfactant), samples corresponding to the end portion region and other regions of the printing plate precursor are prepared, and all coated films on the aluminum support of each sample are removed using a solvent such as water, an organic solvent, or a mixture thereof. The content of the surfactant per unit area can be determined by separating the surfactant in the stripping solution using high performance liquid chromatography (HPLC) (Prominence, manufactured by Shimadzu Corporation), quantifying the surfactant using a corona charged particle detector (Corona CAD, manufactured by Thermo Fisher Scientific Inc.), and converting the obtained value per unit area (m²).

Further, in a case where the hydrophilizing agent is a water-soluble resin, samples corresponding to the end portion region of the printing plate precursor and regions other than the end portion region are prepared, and the Fourier transform infrared absorption spectrum (FT-IR) of the coated film on the aluminum support is measured (device: Nicolet Avater 320 FT-IR (manufactured by Thermo Fisher Scientific Inc., measuring method: microreflection method, measured wave number range: approximately 4000 to 900 cm⁻¹, resolution: 4 cm⁻¹, number of times of integration: 128 times) with respect to each sample. A difference (Xa) in peak intensity is acquired from the spectral difference therebetween based on the specific stretching vibration (for example, C═O stretching vibration) derived from the water-soluble resin. Samples obtained by changing the coating amount of the water-soluble resin to 10 mg/m², 10 mg/m², and 1000 mg/m² are separately prepared, and peak intensity (X) derived from the specific stretching vibration in each coating amount is measured as described above. A calibration curve of the coating amount (mg/m²) with respect to the peak intensity (X) is created, and inclination (A) thereof is acquired. A difference in the content of the water-soluble resin per unit area between the end portion region and other regions is calculated using the difference (Xa) in peak intensity and the inclination (A) of the calibration curve.

Difference in content of water-soluble resin per unit area (mg/m²)=(A)×(Xa)

Further, in a case where the hydrophilizing agent is fine particles, samples corresponding to the end portion region and other regions of the printing plate precursor are prepared, and all coated films on the aluminum support of each sample are removed using a solvent such as water, an organic solvent, or a mixture thereof. Next, the content of the fine particles of the end portion region and other regions per unit area can be determined by performing a centrifugation operation of the stripping solution to separate the fine particles, measuring the mass of the fine particles, and converting the mass per unit area (m²).

Hereinafter, each configuration of the printing plate precursor 10a will be described in detail.

<Aluminum Plate>

The aluminum plate 18 (aluminum support) is a metal, which is dimensionally stable and contains aluminum as a main component, and is formed of aluminum or an aluminum alloy. Examples of the aluminum plate include a pure aluminum plate, an alloy plate containing aluminum as a main component and a trace amount of heteroelements, and a plastic film or paper formed by laminating or depositing aluminum (alloy).

Examples of the heteroelements contained in the aluminum alloy include a silicon element, an iron element, a manganese element, a copper element, a magnesium element, a chromium element, a zinc element, a bismuth element, a nickel element, and a titanium element, and the content of the heteroelements in the alloy is 10% by mass or less with respect to the total mass of the alloy. A pure aluminum plate is suitable as an aluminum plate 18, but completely pure aluminum is difficult to produce because of a smelting technology. Therefore, the alloy may contain a trace amount of hetero elements.

The composition of the aluminum plate 18 is not particularly limited, and publicly known materials can be appropriately used (for example, JIS A 1050, JIS A 1100, JIS A 3103, and JIS A 3005).

The width of the aluminum plate 18 is preferably approximately 400 to 2000 mm, and the thickness thereof is preferably approximately 0.1 to 0.6 mm. The width and the thickness thereof can be appropriately changed depending on the size of the printing press, the size of the printing plate, and the user's desire.

<Anodized Film>

The anodized film 20a is a film to be prepared on a surface of the aluminum plate 18 by performing an anodization treatment, and this film is substantially perpendicular to the film surface and has extremely fine micropores 22a uniformly distributed. The micropores 22a extend along the thickness direction (the aluminum plate 18 side) from the surface (the surface of the anodized film 20a on a side opposite to a side where the aluminum plate 18 side) of the anodized film 20a on the functional layer 16 side.

The average diameter (average opening diameter) of the micropores 22a in the surface of the anodized film 20a is in a range of 13 to 100 nm. From the viewpoint of the balance between the edge stain resistance and the printing durability, the average diameter thereof is preferably in a range of 15 to 80 nm, more preferably in a range of 20 to 50 nm, and still more preferably in a range of 25 nm to 40 nm.

In a case where the average diameter thereof is less than 13 nm, the edge stain resistance deteriorates. Further, in a case where the average diameter thereof is greater than 100 nm, the deinking capability after being left to stand deteriorates.

The average diameter of micropores 22a is calculated as an arithmetic average value obtained by observing 4 sheets (N=4) of the surfaces of the anodized film 20a using a field emission scanning electron microscope (FE-SEM) at a magnification of 150000, measuring the diameters of micropores present in a range of 400×600 nm² in the obtained four sheets of images, and averaging the values.

Further, in a case where the shape of the micropores 22a is not circular, an equivalent circle diameter is used. The “equivalent circle diameter” is a diameter of a circle obtained by assuming the shape of an opening portion of a micropore in the surface of the anodized film as a circle having the same projected area as the projected area of the opening portion.

Further, as a suitable embodiment of the micropores, an embodiment in which the average diameter of the micropores in the surface of the anodized film is in a range of 13 to 30 nm and the maximum diameter inside the micropore is in a range of 40 to 300 nm is exemplified.

The shape of such a micropore is formed by using phosphoric acid during the anodization treatment described below.

The depth of the micropores 22a is not particularly limited, but is preferably in a range of 10 nm to 3000 nm, more preferably in a range of 50 nm to 2000 nm, and still more preferably 300 nm to 1600 nm.

Further, the depth thereof is a value obtained by capturing (150000 times) an image of a cross section of the anodized film 20a, measuring the depth of 25 or more micropores 22a, and averaging the obtained values.

The shape of the micropores 22a is not particularly limited, and the shape thereof in FIG. 2 may be a substantially straight tubular shape (substantially cylindrical shape), but may be a conical shape whose diameter decreases toward the depth direction (thickness direction). Further, the shape of the bottom portion of the micropores 22a is not particularly limited, but may be a curved shape (projection shape) or a planar shape.

The value of the brightness L* in the L*a*b* color system of the surface of the aluminum support 12a on a side of the functional layer 16 (the surface of the anodized film 20a on a side of the functional layer 16) is preferably in a range of 70 to 100.

Here, from the viewpoint that the balance of the image visibility is further excellent, the value thereof is preferably in a range of 75 to 100 and more preferably in a range of 75 to 90.

The brightness L* is measured using a color difference meter Spectro Eye (manufactured by X-Rite Inc.).

The range of a steepness a45 representing the area ratio of a portion having an inclining degree of 45° or greater obtained by extracting a component with a wavelength of 0.2 to 2 μm in the surface of the anodized film 20a on a side of the functional layer 16 is not particularly limited, but is preferably 25% or less, more preferably 20% or less, and still more preferably 18% or less from the viewpoints of the stain resistance and the deinking capability after being left to stand. The lower limit thereof is not particularly limited, but is 5% or greater in many cases.

The steepness a45 is a factor representing the surface shape and is a value acquired according to the following procedures (1) to (3).

(1) The surface shape is measured to acquire three-dimensional data.

The surface shape of the aluminum support 12a on the anodized film 20a side is measured using an atomic force microscope (AFM) to acquire three-dimensional data.

The measurement is performed under the following conditions. Specifically, the aluminum support 12a is cut into a size of 1 cm² and set on a horizontal sample stand that is provided on a piezo scanner, a cantilever is allowed to approach the surface of the sample, scanning is performed in the XY direction when reaching a region where atomic force works, and the unevenness of the sample is captured by the displacement of the piezo in the Z direction. A piezo scanner capable of performing scanning a distance of 150 μm in the XY direction and a distance of 10 μm in the Z direction is used as the piezo scanner. A cantilever having a resonance frequency of 120 kHz to 150 kHz and a sprint frequency of 12 to 20 N/m (SI-DF20, manufactured by Nanoprobes Inc.) is used in a dynamic force mode (DFM) as the cantilever. Further, by carrying out the least squares approximation of the acquired three-dimensional data, the slight inclination of the sample is corrected to acquire a reference surface.

During the measurement, 512×512 points in an area having a size of 25×25 μm on the surface are measured. The resolution in the XY direction is 1.9 the resolution in the Z direction is 1 nm, and the scanning speed is 60 μm/sec.

(2) The correction is performed.

In the calculation of the steepness a45, a component having a wavelength of 0.2 to 2 μm is selected from the three-dimensional data which has been acquired in (1) described above and is corrected. Due to this correction, in a case where a surface of an aluminum support or the like used in the printing plate precursor which has significant unevenness is scanned using a probe of an AFM, a noise occurring in a case where the probe strikes an edge portion of a projection and springs so that a portion other than a pointed end of the probe is brought into contact with a wall surface of a deep depression can be eliminated.

The correction is carried out by performing fast Fourier transformation on the three-dimensional data acquired in (1) described above to acquire the frequency distribution, selecting a component having a wavelength of 0.2 to 2 μm, and performing Fourier inverse transformation.

(3) The steepness a45 is calculated.

Three points adjacent to one another are extracted using the three-dimensional data (f(x, y)) obtained by performing correction in (2) described above, an angle between a small triangle formed of these three points and the reference surface is calculated for all pieces of data to acquire the inclining degree distribution curve. In addition, the sum of the area of the small triangle is acquired and this area is set as the actual area. Based on the inclining degree distribution curve, the steepness a45 (unit: %) which is a ratio of the area of a portion having an inclining degree of 45° or greater to the actual area is calculated.

The range of a specific surface area ΔS which is a value acquired by the following Equation (i) based on a geometric measurement area S₀ and an actual area Sₓ acquired according to an approximation three point method from the three-dimensional data to be obtained by measuring 512×512 points in an area having a size of 25 μm×25 μm on the surface of the anodized film 20a on the functional layer 16 side using an atomic force microscope is not particularly limited, and is 15% or greater in many cases. From the viewpoints of excellent stain resistance, deinking capability after being left to stand, and image visibility, the specific surface area ΔS is preferably 20% or greater, more preferably in a range of 20% to 40%, and still more preferably 25% to 35%.

ΔS=(Sₓ−S₀)/S₀×100(%) (i)

In the measurement of ΔS described above, the three-dimensional data (f(x, y)) is obtained according to the same procedures as in (1) that is to be performed at the time of calculating the steepness a45.

Next, three points adjacent to one another are extracted using the three-dimensional data (f(x, y)) obtained in the above-described manner, the sum of the area of the small triangle formed of these three points is acquired, and this area is set as an actual area Sₓ. The specific surface area ΔS is acquired by Equation (i) described above based on the actual area Sₓ and the geometric measurement area S₀.

[Undercoat Layer]

The undercoat layer 14 is a layer disposed between the aluminum support 12a and the functional layer 16 and improves the adhesion property between the aluminum support 12a and the functional layer 16. As described above, the undercoat layer 14 is a layer provided as necessary and may not be included in the printing plate precursor.

The configuration of the undercoat layer is not particularly limited, but it is preferable that the undercoat layer contains a compound having a betaine structure from the viewpoint of further improving the effects of the present invention.

First, the betaine structure is a structure having at least one cation and at least one anion. Further, the number of cations is typically the same as the number of anions so as to be neutral as a whole. However, according to the present invention, in a case where the number of cations is not the same as the number of anions, the charge is cancelled by having a required amount of counter ions so that the betaine structure is obtained.

It is preferable that the betaine structure is a structure represented by Formula (1), a structure represented by Formula (2), or a structure represented by Formula (3).

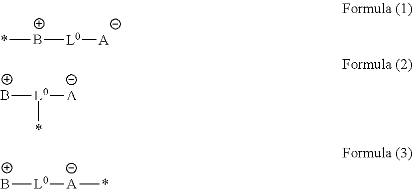

In the formulae, A⁻ represents a structure having an anion, B⁺ represents a structure having a cation, and L⁰ represents a linking group. The symbol “*” represents a linking site (linking position).

It is preferable that A⁻ represents a structure having an anion such as a carboxylate, a sulfonate, a phosphonate, or a phosphinate and B⁺ represents a structure having a cation such as ammonium, phosphonium, iodonium, or sulfonium.

L⁰ represents a linking group. In Formulae (1) and (3), examples of L⁰ include divalent linking groups. Among these, —CO—, —O—, —NH—, a divalent aliphatic group, a divalent aromatic group, or a combination thereof is preferable. In Formula (2), examples of L⁰ include trivalent linking groups.

A linking group having 30 or less carbon atoms including the number of carbon atoms of the following substituent which may be included is preferable as the linking group.

Specific examples of the linking group include an alkylene group (having preferably 1 to 20 carbon atoms and more preferably 1 to 10 carbon atoms) and an arylene group (having preferably 5 to 15 carbon atoms and more preferably 6 to 10 carbon atoms) such as a phenylene group or a xylylene group.

Further, these linking groups may further have substituents.

Examples of the substituent include a halogen atom, a hydroxyl group, a carboxyl group, an amino group, a cyano group, an aryl group, an alkoxy group, an aryloxy group, an acyl group, an alkoxycarbonyl group, an aryloxycarbonyl group, an acyloxy group, a monoalkylamino group, a dialkylamino group, a monoarylamino group, and a diarylamino group.

From the viewpoint of further improving the effects of the present invention, the betaine structure is preferably a structure represented by Formula (i), a structure represented by formula (ii), or a structure represented by Formula (iii) and more preferably a structure represented by Formula (i). The symbol “*” represents a linking site.

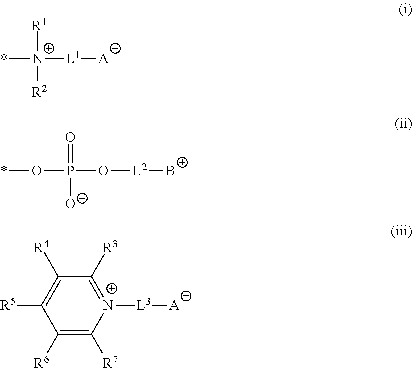

In Formula (i), R¹ and R² each independently represent a hydrogen atom, an alkyl group, an alkenyl group, an alkynyl group, an aryl group, or a heterocyclic group, and R¹ and R² may be linked to each other to form a ring structure.

The ring structure may have heteroatoms such as an oxygen atom. As the ring structure, a 5- to 10-membered ring is preferable and a 5- or 6-membered ring is more preferable.

The number of carbon atoms in R¹ and R² is preferably in a range of 1 to 30 and more preferably in a range of 1 to 20.

From the viewpoint of further improving the effects of the present invention, it is preferable that R¹ and R² represent a hydrogen atom, a methyl group, or an ethyl group.

L¹ represents a divalent linking group and preferably —CO—, —O—, —NH—, a divalent aliphatic group (such as an alkylene group), a divalent aromatic group (such as a phenylene group), or a combination thereof.

It is preferable that L1 represents a linear alkylene group having 3 to 5 carbon atoms.

In Formula (i), A″ represents a structure having an anion and preferably a carboxylate, a sulfonate, a phosphonate, or a phosphinate.

Specific examples thereof include the following structures.

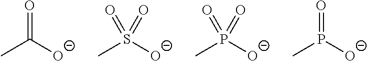

In Formula (i), a combination in which L¹ represents a linear alkylene group having 4 or 5 carbon atoms and A⁻ represents a sulfonate is preferable, and a combination in which L¹ represents a linear alkylene group having 4 carbon atoms and A⁻ represents a sulfonate is more preferable.

In Formula (ii), L² represents a divalent linking group and preferably —CO—, —O—, —NH—, a divalent aliphatic group (such as an alkylene group), a divalent aromatic group (such as a phenylene group), or a combination thereof.

B⁺ represents a structure having a cation and preferably a structure having ammonium, phosphonium, iodonium, or sulfonium. Among these, a structure having ammonium or phosphonium is preferable, and a structure having ammonium is more preferable.

Examples of the structure having a cation include a trimethylammonio group, a triethylammonio group, a tributylammonio group, a benzyldimethylammonio group, a diethylhexylammonio group, a (2-hydroxyethyl)diethylammonio group, a pyridinio group, a N-methylimidazolio group, a N-acridinio group, a trimethylphosphonio group, a triethylphosphonio group, and a triphenylphosphonio group.

In Formula (iii), L³ represents a divalent linking group and preferably —CO—, —O—, —NH—, a divalent aliphatic group (such as an alkylene group), a divalent aromatic group (such as a phenylene group), or a combination thereof.

A⁻ represents a structure having an anion and preferably a carboxylate, a sulfonate, a phosphonate, or a phosphinate. Further, the details and preferred examples thereof are the same as those for A⁻ in Formula (i).

R³ to R⁷ each independently represent a hydrogen atom or a substituent (having preferably 1 to 30 carbon atoms), and at least one of R³ to R⁷ represents a linking site.

At least one of R³ to R⁷ as a linking site may be linked to another site in the compound through a substituent as at least one of R³ to R⁷ or may be directly linked to another site in the compound through a single bond.

Examples of the substituents represented by R³ to R⁷ include a halogen atom, an alkyl group, (such as a cycloalkyl group or a bicycloalkyl group), an alkenyl group (such as a cycloalkenyl group or a bicycloalkenyl group), an alkyl group, an aryl group, a heterocyclic group, a cyano group, a hydroxyl group, a nitro group, a carboxyl group, an alkoxy group, an aryloxy group, a silyloxy group, a heterocyclic oxy group, an acyloxy group, a carbamoyloxy group, an alkoxycarbonyloxy group, an aryloxycarbonyloxy group, an amino group (such as an anilino group), an acylamino group, an aminocarbonylamino group, an alkoxycarbonylamino group, an aryloxycarbonylamino group, a sulfamoylamino group, an alkyl and arylsulfonylamino group, a mercapto group, an alkylthio group, an arylthio group, a heterocyclic thio group, a sulfamoyl group, a sulfo group, an alkyl and arylsulfinyl group, an alkyl and arylsulfonyl group, an acyl group, an aryloxycarbonyl group, an alkoxycarbonyl group, a carbamoyl group, an aryl and heterocyclic azo group, an imide group, a phosphino group, a phosphinyl group, a phosphinyloxy group, a phosphinylamino group, and a silyl group.

From the viewpoint of further improving the effects of the present invention, it is preferable that the compound is a polymer having a repeating unit with a betaine structure (hereinafter, also simply referred to as a “specific polymer”). As the repeating unit with a betaine structure, a repeating unit represented by Formula (A1) is preferable.

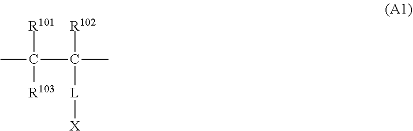

In the formula, R¹⁰¹ to R¹⁰³ each independently represent a hydrogen atom, an alkyl group, or a halogen atom. L represents a single bond or a divalent linking group.

Examples of the divalent linking group include —CO—, —O—, —NH—, a divalent aliphatic group, a divalent aromatic group, and a combination thereof.

Specific examples of L formed of the above-described combination are listed below. In each of the following examples, the left side is bonded to the main chain and the right side is bonded to X.

L1: —CO—O-divalent aliphatic group-

L2: —CO—O-divalent aromatic group-

L3: —CO—NH-divalent aliphatic group-

L4: —CO—NH-divalent aromatic group-

L5: —CO-divalent aliphatic group-

L6: —CO-divalent aromatic group-

L7: —CO-divalent aliphatic group-CO—O-divalent aliphatic group-

L8: —CO-divalent aliphatic group-O—CO-divalent aliphatic group-

L9: —CO-divalent aromatic group-CO—O-divalent aliphatic group-

L10: —CO-divalent aromatic group-O—CO-divalent aliphatic group-

L11: —CO-divalent aliphatic group-CO—O-divalent aromatic group-

L12: —CO-divalent aliphatic group-O—CO-divalent aromatic group-

L13: —CO-divalent aromatic group-CO—O-divalent aromatic group-

L14: —CO-divalent aromatic group-O—CO-divalent aromatic group-

L15: —CO—O-divalent aromatic group-O—CO—NH-divalent aliphatic group-

L16: —CO—O-divalent aliphatic group-O—CO—NH-divalent aliphatic group-

Examples of the divalent aliphatic group include an alkylene group, an alkenylene group, and an alkynylene group.

Examples of the divalent aromatic group include an aryl group. Further, a phenylene group or a naphthylene group is preferable.

X represents a betaine structure. It is preferable that X represents a structure represented by Formula (i), a structure represented by Formula (ii), or a structure represented by Formula (iii).

Particularly, in Formula (A1), a combination in which L represents L1 or L3, X represents a structure represented by Formula (i), and A⁻ in Formula (i) represents a sulfonate group is preferable.

The content of the repeating unit having a betaine structure in the specific polymer is not particularly limited, but is preferably in a range of 20% to 80% by mass, more preferably in a range of 25% to 70% by mass, and still more preferably in a range of 25% to 50% by mass with respect to the total amount of all repeating units constituting the specific polymer from the viewpoint of further improving the effects of the present invention.

The specific polymer may have repeating units other than the repeating unit having a betaine structure.

The specific polymer may have a repeating unit having a structure (hereinafter, also simply referred to as an “interaction structure”) that interacts with the surface of the aluminum support 12a.

Examples of the interaction structure include a carboxylic acid structure, a carboxylate structure, a sulfonic acid structure, a sulfonate structure, a phosphonic acid structure, a phosphonate structure, a phosphoric acid ester structure, a phosphoric acid ester salt structure, a β-diketone structure, and a phenolic hydroxyl group.

Among these, a carboxylic acid structure, a carboxylate structure, a sulfonic acid structure, a sulfonate structure, a phosphonic acid structure, a phosphonate structure, a phosphoric acid ester structure, or a phosphoric acid ester salt structure is preferable.

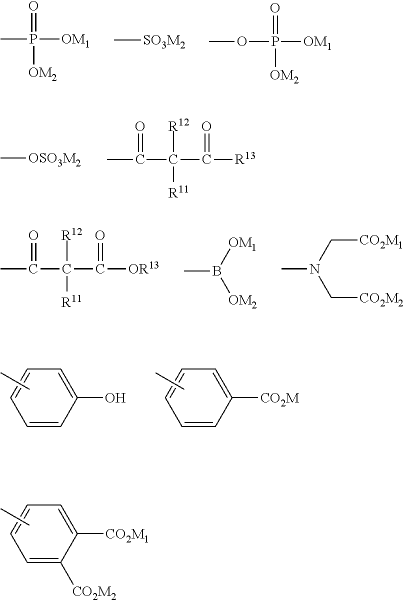

In the formulae, R¹¹ to R¹³ each independently represent a hydrogen atom, an alkyl group, an aryl group, an alkynyl group, or an alkenyl group, and M, M₁, and M₂ each independently represent a hydrogen atom, a metal atom (such as an alkali metal atom such as Na or Li), or an ammonium group. B represents a boron atom.

As the repeating unit having an interaction structure, a repeating unit represented by Formula (A2) is preferable.

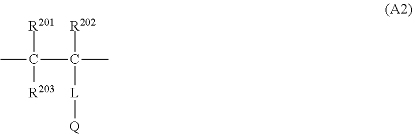

In the formula, R²⁰¹ to R²⁰³ each independently represent a hydrogen atom, an alkyl group (having preferably 1 to 6 carbon atoms), or a halogen atom.

L represents a single bond or a divalent linking group. Examples of the divalent linking group include —CO—, —O—, —NH—, a divalent aliphatic group, a divalent aromatic group, and a combination thereof.

Specific examples of L formed of the above-described combination include the same structures for Formula (A1), and L17 and L18.

—CO—NH— L17:

—CO—O— L18:

Among L1 to L18, L1 to L4, L17, or L18 is preferable.

Q represents an interaction structure, and the preferable aspect thereof is the same as described above.

The content of the repeating unit having an interaction structure in the specific polymer is not particularly limited, but is preferably in a range of 1% to 40% by mass and more preferably in a range of 3% to 30% by mass with respect to the total amount of all repeating units constituting the specific polymer from the viewpoint of further improving the effects of the present invention.

The specific polymer may have a repeating unit that contains a radically polymerizable group.

Examples of the radically polymerizable group include an addition-polymerizable unsaturated bonding group (such as a (meth)acryloyl group, a (meth)acrylamide group, a (meth)acrylonitrile group, an allyl group, a vinyl group, a vinyloxy group, or an alkynyl group) and a functional group capable of chain transfer (such as a mercapto group).

The specific polymer having a repeating unit that contains a radically polymerizable group can be obtained by introducing a radically polymerizable group according to the method described in JP2001-312068A. Excellent developability is exhibited in an unexposed portion, the permeability of the developer is suppressed by the polymerization in an exposed portion, and the adhesiveness and the adhesion property between the aluminum support 12a and the functional layer 16 are improved by using the specific polymer having a repeating unit that contains a radically polymerizable group.

The content of the repeating unit that contains a radically polymerizable group in the specific polymer is not particularly limited, but is preferably in a range of 1% to 30% by mass and more preferably in a range of 3% to 20% by mass with respect to the total amount of all repeating units constituting the specific polymer from the viewpoint of further improving the effects of the present invention.

The content of the compound having a betaine structure in the undercoat layer 14 is not particularly limited, but is preferably 80% by mass or greater and more preferably 90% by mass or greater with respect to the total mass of the undercoat layer.

The upper limit thereof is, for example, 100% by mass.

Hereinbefore, the undercoat layer 14 that contains a compound with a betaine structure has been described, but the undercoat layer may contain another compound.

For example, the undercoat layer may contain a compound that contains a hydrophilic group. Examples of the hydrophilic group include a carboxylic acid group and a sulfonic acid group.

The compound that contains a hydrophilic group may further contain a radically polymerizable group.

<Functional Layer>

Examples of the functional layer 16 include an image recording layer and a non-photosensitive layer. Hereinafter, each layer will be described.

(Image Recording Layer)

As an image recording layer, an image recording layer which can be removed by printing ink and/or dampening water is preferable. It is preferable that the image recording layer is a photosensitive layer.

Hereinafter, each constitutional component of the image recording layer will be described.

(Infrared Absorbing Agent)

It is preferable that the image recording layer contains an infrared absorbing agent.

It is preferable that the infrared absorbing agent has maximum absorption at a wavelength range of 750 to 1400 nm. Particularly, since on-press development is carried out by a printing press under white light in an on-press development type printing plate precursor, a printing plate precursor with excellent developability can be obtained using an infrared absorbing agent having the maximum absorption at a wavelength range of 750 to 1400 nm, which is not easily affected by the white light.

A dye or a pigment is preferable as the infrared absorbing agent.

As the dye, commercially available dyes and known dyes described in the literatures, for example, “Dye Handbook” (edited by The Society of Synthetic Organic Chemistry, Japan, published in 1970) are exemplified.

Examples of the dye include a cyanine coloring agent, a squarylium coloring agent, a pyrylium salt, a nickel thiolate complex, and an indolenine cyanine coloring agent. Among these, a cyanine coloring agent or an indolenine cyanine coloring agent is preferable, a cyanine coloring agent is more preferable, and a cyanine coloring agent represented by Formula (a) is still more preferable.

Formula (a)

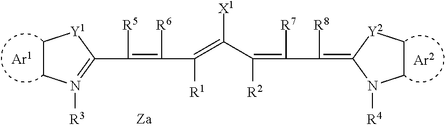

In Formula (a), X¹ represents a hydrogen atom, a halogen atom, —N(R⁹)(R¹⁰), —X²-L¹, or a group shown below.

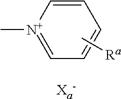

R⁹ and R¹⁰ each independently represent an aromatic hydrocarbon group, an alkyl group, or a hydrogen atom, and R⁹ and R¹⁰ may be bonded to each other to form a ring. Among these, a phenyl group is preferable.

X² represents an oxygen atom or a sulfur atom, and L¹ represents a hydrocarbon group having 1 to 12 carbon atoms which may have heteroatoms (such as N, S, O, a halogen atom, and Se).

Xₐ⁻ has the same definition as that for Zₐ⁻ described below, and R^{a} represents a hydrogen atom, an alkyl group, an aryl group, an amino group, or a halogen atom.

R¹ and R² each independently represent a hydrocarbon group having 1 to 12 carbon atoms. Further, R¹ and R² may be bonded to each other to form a ring, and it is preferable that a 5- or 6-membered ring is formed during the formation of a ring.

Ar¹ and Ar² each independently represent an aromatic hydrocarbon group which may have a substituent (for example, an alkyl group). As the aromatic hydrocarbon group, a benzene ring group or a naphthalene ring group is preferable.

Y¹ and Y² each independently represent a sulfur atom or a dialkyl methylene group having 12 or less carbon atoms.

R³ and R⁴ each independently represent a hydrocarbon group having 20 or less carbon atoms which may have a substituent (such as an alkoxy group).

R⁵, R⁶, R⁷, and R⁸ each independently represent a hydrogen atom or a hydrocarbon group having 12 or less carbon atoms.

Further, Za⁻ represents a counter anion. Here, Za⁻ is not necessary in a case where the cyanine coloring agent represented by Formula (a) has an anionic substituent in the structure thereof and neutralization of the charge is not required. Examples of Za− include a halide ion, a perchlorate ion, a tetrafluoroborate ion, a hexafluorophosphate ion, and a sulfonic acid ion. Among these, a perchlorate ion, a hexafluorophosphate ion, or an arylsulfonic acid ion is preferable.

The above-described infrared absorbing dyes may be used alone or in combination of two or more kinds thereof. Further, infrared absorbing agents other than the infrared absorbing dyes such as pigments may be used in combination. As the pigments, the compounds described in paragraphs [0072] to [0076] in JP2008-195018A are preferable.

The content of the infrared absorbing agent is preferably in a range of 0.05% to 30% by mass and more preferably in a range of 0.1% to 20% by mass with respect to the total mass of the image recording layer.

(Polymerization Initiator)

It is preferable that the image recording layer contains a polymerization initiator.

As the polymerization initiator, a compound (so-called radically polymerization initiator) that generates a radical using light, heat, or the energy of both light and heat and initiates polymerization of a compound containing a polymerizable unsaturated group is preferable.

Examples of the polymerization initiator include a photopolymerization initiator and a thermal polymerization initiator.

As the polymerization initiator, specifically, the polymerization initiators described in paragraphs [0115] to [0141] described in JP2009-255434A can be used.

Further, from the viewpoints of the reactivity and the stability, an oxime ester compound or an onium salt such as a diazonium salt, an iodonium salt, or a sulfonium salt is preferable as the polymerization initiator.

The content of the polymerization initiator is preferably in a range of 0.1% to 50% by mass and more preferably in a range of 0.5% to 30% by mass with respect to the total mass of the image recording layer.

(Polymerizable Compound)

It is preferable that the image recording layer contains a polymerizable compound.

As the polymerizable compound, an addition-polymerizable compound having at least one ethylenically unsaturated bond is preferable. Among the examples, a compound having at least one (preferably two) terminal ethylenically unsaturated bond is more preferable. A so-called radically polymerizable compound is more preferable.

Examples of the polymerizable compound include the polymerizable compounds described in paragraphs [0142] to [0163] of JP2009-255434A.

Further, a urethane-based addition-polymerizable compound produced using the addition reaction between isocyanate and a hydroxyl group is also suitable. Specific examples thereof include a vinyl urethane compound containing two or more polymerizable vinyl groups in one molecule which is obtained by adding a vinyl monomer that contains a hydroxyl group represented by Formula (A) to a polyisocyanate compound containing two or more isocyanate groups in one molecule described in JP1973-041708B (JP-S48-041708B).

CH₂═C(R⁴)COOCH₂CH(R⁵)OH (A)

(Here, R⁴ and R⁵ represent H or CH₃.)

The content of the polymerizable compound is preferably in a range of 3% to 80% by mass and more preferably in a range of 10% to 75% by mass with respect to the total mass of the image recording layer.

(Polymer Compound)

It is preferable that the image recording layer contains a polymer compound.

Specific examples of the polymer compound include an acrylic resin, a polyvinyl acetal resin, a polyurethane resin, a polyurea resin, a polyimide resin, a polyamide resin, an epoxy resin, a methacrylic resin, a polystyrene-based resin, a novolak type phenolic resin, a polyester resin, synthetic rubber, and natural rubber.

The polymer compound may have a crosslinking property in order to improve the film hardness of the image area. In order to allow the polymer compound to have the crosslinking property, a crosslinkable functional group such as an ethylenically unsaturated bond may be introduced to the main chain or a side chain of the polymer. The crosslinkable functional group may be introduced by copolymerization.

As the polymer compound, the polymer compounds (binder polymers) disclosed in paragraphs [0164] to [0172] of JP2009-255434A can be used.

It is preferable that the polymer compound has a hydrophobic main chain and both of a repeating unit which contains a pendant-cyano group (—C≡N) directly bonded to the hydrophobic main chain and a repeating unit which contains a pendant group having a hydrophilic polyalkylene oxide segment.

Examples of the repeating unit that contains a pendant-cyano group include —[CH₂CH(C≡N)-] and —[CH₂C(CH₃)(C≡N)—].

Further, the repeating unit that contains a pendant-cyano group can be derived from an ethylene-based unsaturated monomer (such as acrylonitrile or methacrylonitrile) or a combination thereof.

The poly(alkylene oxide) segment is, for example, an oligomer or polymer that has a block formed of an alkylene oxide unit. Examples of the alkylene oxide unit include an alkylene oxide group having 1 to 6 carbon atoms. Among the examples, an alkylene oxide group having 1 to 3 carbon atoms is preferable.

As a suitable embodiment of the pendant group that contains a poly(alkylene oxide) segment, a group represented by the following formula is exemplified.

—C(═O)O—[(CH₂)ₓO-]_{y}R

In the formula, x represents 1 to 3, y represents 5 to 150, and R represents an alkyl group.

The content of the polymer compound is preferably in a range of 5% to 90% by mass and more preferably in a range of 5% to 70% by mass with respect to the total mass of the image recording layer.

(Thermoplastic Polymer Particles)

The image recording layer may contain thermoplastic polymer particles.

Specific examples of a polymer constituting thermoplastic polymer particles include homopolymers or copolymers of monomers such as acrylate or methacrylate having structures of ethylene, styrene, vinyl chloride, methyl acrylate, ethyl acrylate, methyl methacrylate, ethyl methacrylate, vinylidene chloride, acrylonitrile, vinyl carbazole, and polyalkylene, and mixtures of these. Among these, polystyrene, styrene, a copolymer containing acrylonitrile, and polymethylmethacrylate are more preferable.

The average particle diameter of the thermoplastic polymer particles is preferably in a range of 0.01 to 3.0 μm.

(Surfactant)

The image recording layer may contain a surfactant in order to promote the on-press developability at the time of the start of printing and improve the state of the coated surface.

Examples of the surfactant include a non-ionic surfactant, an anionic surfactant, a cationic surfactant, an amphoteric surfactant, and a fluorine-based surfactant.

As the surfactant, the surfactants disclosed in paragraphs [0175] to [0179] of JP2009-255434A can be used.

The content of the surfactant is preferably in a range of 0.001% to 10% by mass and more preferably in a range of 0.01% to 5% by mass with respect to the total mass of the image recording layer.

The image recording layer may further contain compounds other than those described above as necessary.

Examples of other compounds include the coloring agent, the printing-out agent, the polymerization inhibitor, the higher fatty acid derivative, the plasticizer, the inorganic particles, and the low-molecular-weight hydrophilic compound disclosed in paragraphs [0181] to [0190] of JP2009-255434A.

Other examples thereof include the hydrophobic precursor (fine particles capable of converting an image recording layer to be hydrophobic at the time addition of heat), the low-molecular-weight hydrophilic compound, the sensitizing agent (for example, a phosphonium compound, a nitrogen-containing low-molecular-weight compound, or an ammonium group-containing polymer), and the chain transfer agent disclosed in paragraphs [0191] to [0217] of JP2012-187907A.

(Non-Photosensitive Layer)

The non-photosensitive layer is a layer which can be removed by at least one of acidic to alkaline dampening water or printing ink on a printing press.

The non-photosensitive layer may contain a polymer compound. As the polymer compound, a polymer compound which may be contained in the image recording layer is exemplified.

As another suitable embodiment of the polymer compound, a polymer compound having a polyoxyalkylene chain in a side chain is exemplified. In a case where the non-photosensitive layer contains the polymer compound having a polyoxyalkylene chain in a side chain, the permeability of dampening water is promoted, and the on-press developability is improved.

As the alkylene oxide in the polyoxyalkylene chain, an alkylene oxide having 2 to 6 carbon atoms is preferable, and ethylene oxide or propylene oxide is more preferable.

It is preferable that the polymer compound having a polyoxyalkylene chain in a side chain has a repeating unit represented by Formula (2).

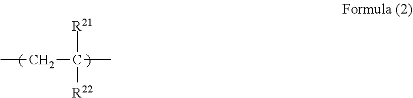

In Formula (2), R^{2′} represents a hydrogen atom or a methyl group.

R²² represents a substituent.

It is preferable that R²² represents an ester group, an amide group, a cyano group, a hydroxy group, or an aryl group. Among these, an ester group, an amide group, or a phenyl group which may have a substituent is preferable. Examples of the substituent of the phenyl group include an alkyl group, an aralkyl group, an alkoxy group, and an acetoxymethyl group.

The polymer compound having a polyoxyalkylene chain in a side chain may contain a crosslinkable functional group.

Preferred examples of the crosslinkable functional group include an ethylenically unsaturated group such as a (meth)acrylic group, a vinyl group, an allyl group, or a styryl group; and an epoxy group.

Other preferred examples of the polymer compound contained in the non-photosensitive layer include a polymer compound having a polymer chain bonded to a nucleus using a tetrafunctional to decafunctional polyfunctional thiol as the nucleus.

The non-photosensitive layer may contain other compounds as necessary.

The non-photosensitive layer may contain a low-molecular-weight hydrophilic compound, a plasticizer, a surfactant, a coloring agent, a printing-out agent, a polymerization inhibitor, a higher fatty acid derivative, inorganic fine particles, an inorganic layered compound, a co-sensitizer, and a chain transfer agent.

Examples of the embodiment of the non-photosensitive layer include the embodiment described in paragraphs [0078] to [0116] of JP2017-065184A.

<Other Components>

The printing plate precursor according to the embodiment of the present invention may include layers other than the aluminum support 12a, the undercoat layer 14, and the functional layer 16 described above.

For example, for the purpose of preventing occurrence of scratches on the functional layer 16, blocking oxygen, and preventing abrasion at the time of exposure to a high-illuminance laser, a protective layer may be provided on the functional layer 16 as necessary.

Examples of the material used for the protective layer include the materials (such as a water-soluble polymer compound and an inorganic layered compound) described in paragraphs [0213] to [0227] of JP2009-255434A.

It is preferable that an end portion of the printing plate precursor according to the embodiment of the present invention has a sagging shape. The printing plate precursor having an end portion with a sagging shape has excellent edge stain resistance.

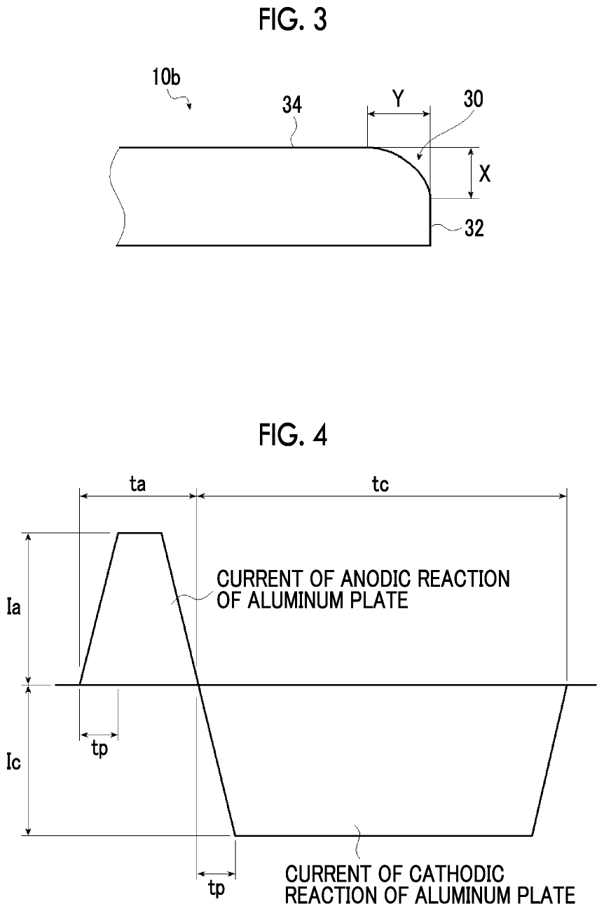

FIG. 3 is an enlarged view illustrating an example of the cross-sectional shape of the printing plate precursor.

In FIG. 3, a printing plate precursor 10b has an end portion with a sagging shape 30. A distance X between the upper end (the boundary between the sagging shape 30 and an end surface 32) of the end surface 32 of the printing plate precursor 10b and the extended line of the surface 34 of the functional layer (the surface of a protective layer in a case where a protective layer has been formed) is referred to as a “sagging amount”. Further, a distance Y between the point where a surface 34 of the functional layer of the printing plate precursor 10 begins to sag and the extended line of the end surface 32 is referred to as a “sagging width”.

The sagging amount of the end portion of the printing plate precursor is preferably 20 μm or greater and more preferably 40 μm or greater. From the viewpoint of preventing deterioration of the on-press developability due to degradation of the surface state of the end portion, the sagging amount is preferably 150 μm.

From the viewpoint of suppressing occurrence of cracks, the sagging width is preferably in a range of 70 to 300 μm and more preferably in a range of 80 to 250 μm.

The formation of the end portion with the sagging shape can be adjusted by, for example, the cutting conditions for the printing plate precursor. The cutting method will be described below.

Further, the embodiment of the printing plate precursor using the undercoat layer 14 has been described in FIG. 1. However, as described above, the printing plate precursor may not include the undercoat layer.

In a case where the undercoat layer is not provided, a functional layer may be formed after a hydrophilization treatment is performed on the aluminum support.

Examples of the hydrophilization treatment include known methods described in paragraphs [0109] to [0114] of JP2005-254638A. Among the examples, it is preferable that the hydrophilization treatment is performed using a method of immersing the support in an aqueous solution of alkali metal silicate such as sodium silicate or potassium silicate or a method of coating the support with a hydrophilic vinyl polymer of a hydrophilic compound to form a hydrophilic undercoat layer.

The hydrophilization treatment using an aqueous solution of alkali metal silicate such as sodium silicate or potassium silicate can be performed according to the procedures and the methods described in UP2714066A and U.S. Pat. No. 3,181,461A.

<Method of Producing Printing Plate Precursor>

The printing plate precursor has a configuration in which an end portion region contains a higher content of the hydrophilizing agent than that of other regions, and the average diameter of micropores in the surface of the anodized film is in a range of 13 to 100 nm. A method of producing the printing plate precursor is not particularly limited as long as the printing plate precursor having such a configuration is obtained.

Hereinafter, the method of producing the printing plate precursor according to the embodiment of the present invention will be described.

First, an aluminum support is produced during the production of the printing plate precursor.

As the method of producing an aluminum support, for example, as the method of producing the aluminum support illustrated in FIG. 1, a production method of sequentially performing the following steps is preferable.

(Roughening treatment step) A step of performing a roughening treatment on an aluminum plate

(Anodization treatment step) A step of anodizing the aluminum plate which has been subjected to the roughening treatment

(Pore widening treatment step) A step of widening the diameter of micropores in the anodized film by bringing the aluminum plate having the anodized film obtained in the anodization treatment step into contact with an acid aqueous solution or an alkali aqueous solution

Hereinafter, the procedures of each step will be described in detail.

(Roughening Treatment Step)

The roughening treatment step is a step of performing a roughening treatment including an electrochemical roughening treatment on a surface of an aluminum plate. It is preferable that the present step is performed before the anodization treatment step described below, but may not be performed in a case where the surface of the aluminum plate already has a preferable surface shape.

The roughening treatment may be carried out by performing only an electrochemical roughening treatment, but may be carried out by combining an electrochemical roughening treatment and a mechanical roughening treatment and/or a chemical roughening treatment.

In a case where the mechanical roughening treatment is combined with the electrochemical roughening treatment, it is preferable that the electrochemical roughening treatment is performed after the mechanical roughening treatment.

It is preferable that the electrochemical roughening treatment is performed in an aqueous solution mainly containing nitric acid or hydrochloric acid using the direct current or the alternating current.

The method of performing the mechanical roughening treatment is not particularly limited, and the methods described in JP1975-040047B (JP-S50-040047B) are exemplified.

The chemical roughening treatment is also not particularly limited, and known methods are exemplified.

It is preferable that a chemical etching treatment described below is performed after the mechanical roughening treatment.

The chemical etching treatment to be performed after the mechanical roughening treatment is performed in order to smooth an edge portion of the uneven shape of the surface of the aluminum plate, prevent the ink from being caught during printing, improve the stain resistance of the printing plate, and remove unnecessary matter such as abrasive material particles remaining on the surface.

Examples of the chemical etching treatment include etching carried out using an acid and etching carried out using an alkali, and a chemical etching treatment (hereinafter, also referred to as an “alkali etching treatment”) carried out using an alkali aqueous solution is exemplified as a particularly excellent method in terms of etching efficiency.

An alkali agent used for the alkali aqueous solution is not particularly limited, and examples thereof include caustic soda, caustic potash, sodium metasilicate, soda carbonate, soda aluminate, and soda gluconate.

The alkali aqueous solution may contain aluminum ions.

The concentration of the alkali agent in the alkali aqueous solution is preferably 0.01% by mass or greater, more preferably 3% by mass or greater, and preferably 30% by mass or less.

In a case where the alkali etching treatment is performed, it is preferable that the chemical etching treatment (hereinafter, also referred to as a “desmutting treatment”) is performed using an acidic aqueous solution at a low temperature in order to remove a product generated due to the alkali etching treatment.

The acid used for the acidic aqueous solution is not particularly limited, and examples thereof include sulfuric acid, nitric acid, and hydrochloric acid. Further, the temperature of the acidic aqueous solution is preferably in a range of 20 to 80° C.

It is preferable that the roughening treatment step is performed according to a method of performing the treatments shown in an A aspect or a B aspect in order described below.

(A Aspect)

(2) A chemical etching treatment carried out using an alkali aqueous solution (first alkali etching treatment)

(3) A chemical etching treatment carried out using an acidic aqueous solution (first desmutting treatment)

(4) An electrochemical roughening treatment carried out using an aqueous solution that mainly contains nitric acid (first electrochemical roughening treatment)

(5) A chemical etching treatment carried out using an alkali aqueous solution (second alkali etching treatment)

(6) A chemical etching treatment carried out using an acidic aqueous solution (second desmutting treatment)

(7) An electrochemical roughening treatment carried out in an aqueous solution that mainly contains hydrochloric acid (second electrochemical roughening treatment)

(8) A chemical etching treatment carried out using an alkali aqueous solution (third alkali etching treatment)

(9) A chemical etching treatment carried out using an acidic aqueous solution (third desmutting treatment)

(B Aspect)

(10) A chemical etching treatment carried out using an alkali aqueous solution (fourth alkali etching treatment)

(11) A chemical etching treatment carried out using an acidic aqueous solution (fourth desmutting treatment)

(12) An electrochemical roughening treatment carried out using an aqueous solution that mainly contains hydrochloric acid (third electrochemical roughening treatment)

(13) A chemical etching treatment carried out using an alkali aqueous solution (fifth alkali etching treatment)

(14) A chemical etching treatment carried out using an acidic aqueous solution (fifth desmutting treatment)

The mechanical roughening treatment (1) may be performed before the treatment (2) of the A aspect described above or before the treatment (10) of the B aspect described above, as necessary.

The amount of the aluminum plate to be dissolved in the first alkali etching treatment and the fourth alkali etching treatment is preferably in a range of 0.5 to 30 g/m² and more preferably in a range of 1.0 to 20 g/m².

As the aqueous solution that mainly contains nitric acid used for the first electrochemical roughening treatment according to the A aspect, an aqueous solution used for an electrochemical roughening treatment carried out using the direct current or the alternating current is exemplified. For example, an aqueous solution obtained by adding aluminum nitrate, sodium nitrate, or ammonium nitrate to 1 to 100 g/L of a nitric acid aqueous solution is exemplified.

As the aqueous solution that mainly contains hydrochloric acid used for the second electrochemical roughening treatment according to the A aspect and the third electrochemical roughening treatment according to the B aspect, a typical aqueous solution used for an electrochemical roughening treatment carried out using the direct current or the alternating current is exemplified. For example, an aqueous solution obtained by adding 0 to 30 g/L of sulfuric acid to a 1 to 100 g/L hydrochloric acid aqueous solution is exemplified. Further, nitrate ions such as aluminum nitrate, sodium nitrate, and ammonium nitrate; and hydrochloride ions such as aluminum chloride, sodium chloride, and ammonium chloride may be added to this solution.

The AC power source waveform of the electrochemical roughening treatment may use a sine wave, a square wave, a trapezoidal wave, and a triangular wave. The frequency is preferably in a range of 0.1 to 250 Hz.

FIG. 4 is a graph showing an example of an alternating waveform current waveform diagram used for the electrochemical roughening treatment.

In FIG. 4, ta represents an anode reaction time, tc represents a cathode reaction time, tp represents a time taken for the current to reach the peak from 0, Ia represents the peak current on an anode cycle side, and Ic represents the peak current on a cathode cycle side. In the trapezoidal wave, the time tp taken for the current to reach the peak from 0 is preferably in a range of 1 to 10 msec. As the preferable conditions for one cycle of the alternating current used for the electrochemical roughening, a ratio tc/ta of the cathode reaction time tc to the anode reaction time ta of the aluminum plate is in a range of 1 to 20, a ratio Qc/Qa of an electric quantity Qc at the time of the aluminum plate serving as an anode to an electric quantity Qa at the time of the aluminum plate serving as an anode is in a range of 0.3 to 20, and the anode reaction time to is in a range of 5 to 1000 msec. The current density is preferably in a range of 10 to 200 A/dm² in both of an anode cycle side Ia and a cathode cycle side Ic of the current in terms of the peak value of the trapezoidal wave. The value of Ic/Ia is preferably in a range of 0.3 to 20. The total amount of the electricity used for the anode reaction of the aluminum plate at the time when the electrochemical roughening is completed is preferably in a range of 25 to 1000 C/dm².

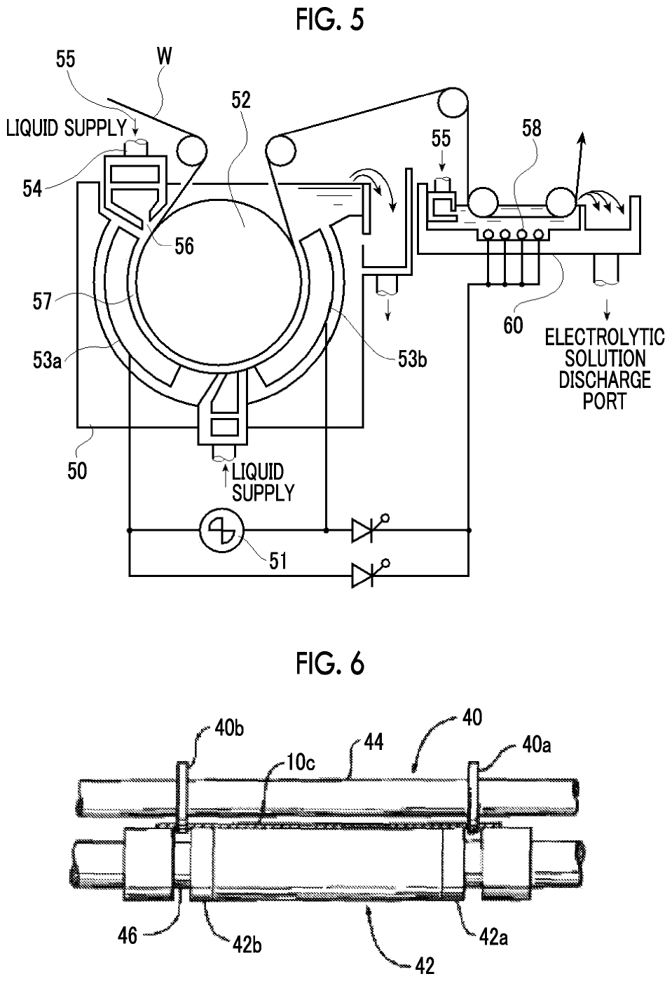

A device illustrated in FIG. 5 can be used for the electrochemical roughening carried out using the alternating current.

FIG. 5 is a side view illustrating an example of a radial type cell in the electrochemical roughening treatment carried out using the alternating current.

In FIG. 5, the reference numeral 50 represents a main electrolytic cell, the reference numeral 51 represents an AC power source, the reference numeral 52 represents a radial drum roller, the reference numerals 53a and 53b represent a main pole, the reference numeral 54 represents an electrolytic solution supply port, the reference numeral 55 represents an electrolytic solution, the reference numeral 56 represents a slit, the reference numeral 57 represents an electrolytic solution passage, the reference numeral 58 represents an auxiliary anode, the reference numeral 60 represents an auxiliary anode cell, and the symbol W represents an aluminum plate. In a case where two or more electrolytic cells are used, the electrolysis conditions may be the same as or different from each other.

The aluminum plate W is wound around the radial drum roller 52 disposed by being immersed in the main electrolytic cell 50 and is electrolyzed by the main poles 53a and 53b connected to the AC power source 51 in the transport process. The electrolytic solution 55 is supplied to the electrolytic solution passage 57 disposed between the radial drum roller 52 and the main pole 53a and between the radial drum roller 52 and the main pole 53b through the slit 56 from the electrolytic solution supply port 54. The aluminum plate W which has been treated in the main electrolytic cell 50 is electrolyzed in the auxiliary anode cell 60. The auxiliary anode 58 is disposed in the auxiliary anode cell 60 so as to face the aluminum plate W and the electrolytic solution 55 is supplied so as to flow through the space between the auxiliary anode 58 and the aluminum plate W.

From the viewpoint of easily producing a predetermined printing plate precursor, the amount of the aluminum plate to be dissolved in the second alkali etching treatment is preferably 1.0 g/m² or greater and more preferably in a range of 2.0 g/m² to 10 g/m².

From the viewpoint of easily producing a predetermined printing plate precursor, the amount of the aluminum plate to be dissolved in the third alkali etching treatment and the fourth alkali etching treatment is preferably 0.01 to 0.8 g/m² and more preferably in a range of 0.05 to 0.3 g/m².

In the chemical etching treatments (first to fifth desmutting treatments) carried out using an acidic aqueous solution, an acidic aqueous solution containing phosphoric acid, nitric acid, sulfuric acid, chromic acid, hydrochloric acid, or mixed acids obtained by mixing two or more of these acids is suitably used. The concentration of the acidic aqueous solution is preferably in a range of 0.5% to 60% by mass.

Anodization Treatment Step

The procedures of the anodization treatment step are not particularly limited as long as the above-described micropores are obtained, and known methods are exemplified.

In the anodization treatment step, an aqueous solution containing sulfuric acid, phosphoric acid, oxalic acid, and the like can be used as an electrolytic cell. For example, the concentration of the sulfuric acid is in a range of 100 to 300 g/L.

The conditions for the anodization treatment are appropriately set depending on the electrolytic solution. As an example of the conditions, the liquid temperature is in a range of 5 to 70° C. (preferably in a range of 10 to 60° C.), the current density is in a range of 0.5 to 60 A/dm² (preferably in a range of 5 to 60 A/dm²), the voltage is in a range of 1 to 100 V (preferably in a range of 5 to 50 V), the electrolysis time is in a range of 1 to 100 seconds (preferably in a range of 5 to 60 seconds), and the coated film amount is in a range of 0.1 to 5 g/m² (preferably in a range of 0.2 to 3 g/m²).

(Pore Widening Treatment)

The pore widening treatment is a treatment (pore diameter widening treatment) of widening the diameter (pore diameter) of micropores present in the anodized film formed by the above-described anodization treatment step.

The pore widening treatment can be performed by bringing the aluminum plate obtained in the anodization treatment step into contact with an acid aqueous solution or an alkali aqueous solution. The method of bringing the aluminum plate into contact with the solution is not particularly limited, and examples thereof include an immersion method and a spray method.

Examples of the method of introducing the hydrophilizing agent to the end portion region of the printing plate precursor include a method of applying a coating solution that contains the hydrophilizing agent to the end portion region of the printing plate precursor in the process of producing the printing plate precursor. The timing of applying the coating solution that contains the hydrophilizing agent to the end portion region of the printing plate precursor may be any time in the process of producing the printing plate precursor and preferably before or after the step of forming each constituent layer, that is, before the coating of the undermost layer (for example, the undercoat layer) and after the drying of the uppermost layer (for example, the protective layer).

The printing plate precursor may be cut before or after the coating solution that contains the hydrophilizing agent to the end portion region of the printing plate precursor.

That is, the printing plate precursor may be cut such that the end portion region of the printing plate precursor is formed after the coating solution that contains the hydrophilizing agent is applied to a position corresponding to the end portion region of the printing plate precursor in the step of forming the constituent layer of the printing plate precursor; or the coating solution that contains the hydrophilizing agent may be applied to the end portion region of the printing plate precursor after the printing plate precursor produced by performing the step of forming the constituent layer of the printing plate precursor is cut. Here, the position corresponding to the end portion region indicates the position that can form the region of the plate surface on the functional layer side which extends to a distance of 5 mm inward from the end portions in the cut printing plate precursor. Accordingly, the position corresponding to the end portion region may be a position in the vicinity of an end of the printing plate precursor or a position in the vicinity of the center of the printing plate precursor in the process of producing the printing plate precursor. In the latter case, the printing plate precursor is cut such that the end portion region is formed according to the region coated with the hydrophilizing agent, thereby obtaining the printing plate precursor having the end portion region.

For example, the following method is exemplified as the embodiment in which the printing plate precursor is cut such that the end portion region of the printing plate precursor is formed after the coating solution that contains the hydrophilizing agent is applied to the position corresponding to the end portion region of the printing plate precursor in the step of forming the constituent layer of the printing plate precursor.

In the printing plate precursor having a functional layer on the aluminum support, a method of producing the printing plate precursor which includes a step a of forming the functional layer, a step b of coating and overlapping a part of the region of the functional layer formed by the step a with the coating solution that contains the hydrophilizing agent, and a step c of cutting the region coated with the coating solution to be in a range of the plate surface on the functional layer side which extends to a distance of 5 mm inward from the end portions of the cut printing plate precursor may be performed in order of the step a and the step b on the aluminum support or in order of the step b, the step a, and then the step c on the aluminum plate.

Further, a step e of forming a protective layer may be performed after the step a and before the step c.

In the printing plate precursor having an undercoat layer and a functional layer on the aluminum support, a method of producing the printing plate precursor which includes the step a of forming the functional layer, the step b of coating and overlapping a part of the region of the functional layer formed by the step a with the coating solution that contains the hydrophilizing agent, the step c of cutting the region coated with the coating solution to be in a range of the plate surface on the functional layer side which extends to a distance of 5 mm inward from the end portions of the cut printing plate precursor, and a step d of forming the undercoat layer may be performed in order of the step b, the step d, and the step a, in order of the step d, the step b, and the step a, or in order of the step d, the step a, the step b, and the step c on the aluminum support.

In the printing plate precursor having an undercoat layer, a functional layer, and a protective layer on the aluminum support, a method of producing the printing plate precursor which includes the step a of forming the functional layer, the step b of coating and overlapping a part of the region of the functional layer formed by the step a with the coating solution that contains the hydrophilizing agent, the step c of cutting the region coated with the coating solution to be in a range of the plate surface on the functional layer side which extends to a distance of 5 mm inward from the end portions of the cut printing plate precursor, the step d of forming the undercoat layer, and the step e of forming the protective layer may be performed in order of the step b, the step d, the step a, and the step e, in order of the step d, the step b, the step a, and the step e, in order of the step d, the step a, the step b, and the step e, or in order of the step d, the step a, the step e, the step b, and the step c on the aluminum support.

For example, the following method is preferable as the embodiment in which the coating solution that contains the hydrophilizing agent is applied to the end portion region of the printing plate precursor after the printing plate precursor produced by performing the step of forming the constituent layer of the printing plate precursor is cut.

In the printing plate precursor having a functional layer on the aluminum support, a method of producing the printing plate precursor which includes the step a of forming the functional layer and a step f of coating the region of the plate surface on the functional layer side which extends to a distance of 5 mm inward from the end portions of the printing plate precursor with the coating solution that contains the hydrophilizing agent may be performed in order of the step a and the step f on the aluminum support.

Further, the step e of forming the protective layer may be performed on the functional layer after the step a and before the step f.

In the printing plate precursor having an undercoat layer and an image recording layer on the aluminum support in this order, a method of producing the printing plate precursor which includes the step a of forming the functional layer, the step f of coating the region of the plate surface on the functional layer side which extends to a distance of 5 mm inward from the end portions of the printing plate precursor with the coating solution that contains the hydrophilizing agent, and the step d of forming the undercoat layer may be performed in order of the step d, the step a, and the step f on the aluminum support.

In the printing plate precursor having an undercoat layer, an image recording layer, and a protective layer on the aluminum support in this order, a method of producing the printing plate precursor which includes the step a of forming the functional layer, the step f of coating the region of the plate surface on the functional layer side which extends to a distance of 5 mm inward from the end portions of the printing plate precursor with the coating solution that contains the hydrophilizing agent, the step d of forming the undercoat layer, and the step e of forming a protective layer may be performed in order of the step d, the step a, the step e, and the step f on the aluminum support.

The step of forming the constituent layer includes at least the step of coating the constituent layer with the solution. The step of drying the coating layer after the coating of the constituent layer is not necessarily required for the step of forming the constituent layer. For example, the aluminum support can be coated with the undercoat layer and then coated with the coating solution that contains the hydrophilizing agent without being dried.

In this case, the hydrophilizing agent is considered to be present not only on the undercoat layer but also in the undercoat layer.

Further, in a case where the functional layer is an image recording layer, the step of applying the coating solution that contains the hydrophilizing agent may be performed after the exposure treatment or the development. In a case where the above-described step is performed after the development, the edge stain resistance becomes excellent.

Hereinafter, typical procedures for the step of applying the coating solution that contains the hydrophilizing agent, the step of forming the undercoat layer, the step of forming the functional layer, the step of forming the protective layer, and the step of the cutting will be described.

(Step of Applying Coating Solution that Contains Hydrophilizing Agent (Edge Treatment))

The kind of the hydrophilizing agent is not particularly limited, but a water-soluble compound is preferable. As the hydrophilizing agent, a compound in which 0.5 g thereof or greater is dissolved in 100 g of water at 20° C. is preferable, and a compound in which 2 g thereof or greater is dissolved therein is more preferable.

A phosphoric acid compound is exemplified as one suitable embodiment of the hydrophilizing agent.

The phosphoric acid compound includes phosphoric acid, a salt thereof, and an ester thereof. Examples thereof include phosphoric acid, metaphosphoric acid, ammonium monophosphate, ammonium diphosphate, sodium dihydrogen phosphate, sodium monohydrogen phosphate, potassium monophosphate, potassium diphosphate, sodium tripolyphosphate, potassium pyrophosphate, and sodium hexametaphosphate. Among these, sodium dihydrogen phosphate, sodium monohydrogen phosphate, or sodium hexametaphosphate is preferable.

As the phosphoric acid compound, a polymer compound is preferable, and a polymer compound that contains a phosphoric acid ester group is more preferable.

Examples of the polymer compound that contains a phosphoric acid ester group include a polymer formed of one or more monomers containing a phosphoric acid ester group in a molecule, a copolymer of one or more monomers containing a phosphoric acid ester group and one or more monomers that do not contain a phosphoric acid ester group, and a polymer obtained by introducing a phosphoric acid ester group to a polymer that does not contain a phosphoric acid ester group using a polymer reaction.

Examples of the monomer containing a phosphoric acid group or a salt thereof include mono(2-(meth)acryloyloxyethyl) acid phosphate, mono(3-(meth)acryloyloxypropyl) acid phosphate, mono(3-(meth)acryloyloxy-2-hydroxypropyl) acid phosphate, mono(2-(meth)acryloyl oxy-3-hydroxypropyl) acid phosphate, mono(3-chloro-2-(meth)acryloyloxypropyl)acid phosphate, mono(3-(meth)acryloyloxy-3-chloro-2-hydroxypropyl) acid phosphate, mono((meth)acryloyloxypolyethylene glycol) acid phosphate, mono((meth)acryloyloxypolypropylene glycol) acid phosphate, allyl alcohol acid phosphate, and salts of these phosphoric acid residues.

As the monomer that does not contain a phosphoric acid ester group in the copolymer, a monomer containing a hydrophilic group is preferable. Examples of the hydrophilic group include a hydroxy group, an alkylene oxide structure, an amino group, an ammonium group, and an amide group. Among these, a hydroxy group, an alkylene oxide structure, or an amide group is preferable, an alkylene oxide structure having 1 to 20 alkylene oxide units with 2 or 3 carbon atoms is more preferable, and a polyethylene oxide structure having 2 to 10 ethylene oxide units is still more preferable.

Examples thereof include 2-hydroxyethyl acrylate, ethoxy diethylene glycol acrylate, methoxy triethylene glycol acrylate, poly(oxyethylene) methacrylate, N-isopropyl acrylamide, and acrylamide.

The content of the repeating unit that contains a phosphoric acid ester group in the polymer compound containing a phosphoric acid ester group is preferably in a range of 1% to 100% by mole, more preferably in a range of 5% to 100% by mole, and still more preferably in a range of 10% to 100% by mole with respect to the total amount of all repeating units in the polymer compound.

The mass average molecular weight of the polymer compound that contains a phosphoric acid ester group is preferably in a range of 5000 to 1000000, more preferably in a range of 7000 to 700000, and still more preferably in a range of 10000 to 500000.

A phosphonic acid compound is exemplified as one suitable embodiment of the hydrophilizing agent.

The phosphonic acid compound includes phosphonic acid, a salt thereof, and an ester thereof. Examples thereof include ethyl phosphonic acid, propyl phosphonic acid, isopropyl phosphonic acid, butyl phosphonic acid, hexyl phosphonic acid, octyl phosphonic acid, dodecyl phosphonic acid, octadecyl phosphonic acid, 2-hydroxyethylphosphonic acid and sodium salts thereof or potassium salts thereof; alkyl phosphonic acid monoalkyl ester such as methyl methylphosphonate, methyl ethylphosphonate, or methyl 2-hydroxyethylphosphonate and sodium salts thereof or potassium salts thereof; alkylene diphosphonic acid such as methylene diphosphonic acid or ethylene diphosphonic acid and sodium salts thereof or potassium salts thereof; and polyvinyl phosphonic acid.

A polymer compound is preferable as the phosphonic acid compound.

Preferred examples of the polymer compound as the phosphonic acid compound include polyvinyl phosphonic acid, a polymer formed of one or more monomers containing a phosphonic acid group or a phosphonic acid monoester group in a molecule, and a copolymer of one or more monomers containing a phosphonic acid group or a phosphonic acid monoester group and one or more monomers that do not contain both a phosphonic acid group and a phosphonic acid mono ester group.

Examples of the monomer that contains a phosphonic acid group or a salt thereof include vinylphosphonic acid, ethyl phosphonic acid monovinyl ester, (meth)acryloylaminomethylphosphonic acid, 3-(meth)acryloyloxypropylphosphonic acid, and salts of these phosphonic acid residues.

Preferred examples of the polymer compound include a homopolymer of a monomer that contains a phosphonic acid ester group and a copolymer of a monomer containing a phosphonic acid ester group and a monomer that does not contain a phosphonic acid ester group.

A monomer containing a hydrophilic group is preferable as the monomer that does not contain a phosphonic acid ester group in the copolymer. Examples of the monomer containing a hydrophilic group include 2-hydroxyethyl acrylate, ethoxydiethylene glycol acrylate, methoxytriethylene glycol acrylate, poly(oxyethylene) methacrylate, N-isopropylacrylamide, and acrylamide.

The content of the repeating unit that contains a phosphonic acid ester group in the polymer compound containing a phosphonic acid ester group is preferably in a range of 1% to 100% by mole, more preferably in a range of 3 100% by mole, and still more preferably in a range of 5 to 100% by mole with respect to the total amount of all repeating units of the polymer compound.

The mass average molecular weight of the polymer compound that contains a phosphonic acid ester group is preferably in a range of 5000 to 1000000, more preferably in a range of 7000 to 700000, and still more preferably in a range of 10000 to 500000.

A water-soluble resin is exemplified as one suitable embodiment of the hydrophilizing agent.

Examples of the water-soluble resin include water-soluble resins classified as polysaccharides, polyvinyl alcohol, polyvinylpyrrolidone, polyacrylamide and a copolymer thereof, a vinyl methyl ether/maleic acid anhydride copolymer, a vinyl acetate/maleic acid anhydride copolymer, and a styrene/maleic acid anhydride copolymer.

Examples of the polysaccharides include starch derivatives (such as dextrin, enzymatically decomposed dextrin, hydroxypropylated starch, carboxymethylated starch, phosphorylated starch, polyoxyalkylene grafted starch, and cyclodextrin), celluloses (such as carboxymethyl cellulose, carboxyethyl cellulose, methyl cellulose, hydroxypropyl cellulose, and methylpropyl cellulose), carrageenan, alginic acid, guar gum, locust bean gum, xanthan gum, gum Arabic, and soy polysaccharides.

Preferred examples of the water-soluble resin include starch derivatives such as dextrin and polyoxyalkylene grafted starch, gum Arabic, carboxymethyl cellulose, and soy polysaccharides.

An anionic surfactant and a non-ionic surfactant are exemplified as one suitable embodiment of the hydrophilizing agent.

Examples of the anionic surfactant include those described in paragraph [0022] of JP2014-104631A, and the content thereof are incorporated in the specification of the present application.

Preferred examples of the anionic surfactant include dialkyl sulfosuccinates, alkyl sulfuric acid ester salts, polyoxyethylene aryl ether sulfuric acid ester salts, and alkyl naphthalene sulfonates.

As the anionic surfactant, an anionic surfactant represented by Formula (I-A) or an anionic surfactant represented by Formula (I-B) is preferable.

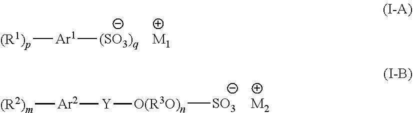

In formula (I-A), R¹ represents a linear or branched alkyl group having 1 to 20 carbon atoms, p represents 0, 1, or 2, Ar¹ represents an aryl group having 6 to 10 carbon atoms, q represents 1, 2, or 3, and M₁⁺ represents Na⁺, K⁺, Li⁺, or NH₄⁺. In a case where p represents 2, a plurality of R¹'s may be the same as or different from one another.

In Formula (I-B), R² represents a linear or branched alkyl group having 1 to 20 carbon atoms, m represents 0, 1, or 2, Ar² represents an aryl group having 6 to 10 carbon atoms, Y represents a single bond or an alkylene group having 1 to 10 carbon atoms, R³ represents a linear or branched alkylene group having 1 to 5 carbon atoms, n represents an integer of 1 to 100, and M₂⁺ represents Na⁺, K⁺, Li⁺, or NH₄⁺. In a case where m represents 2, a plurality of R²'s may be the same as or different from one another. Further, in a case where n represents 2 or greater, a plurality of R³'s may be the same as or different from one another.

In Formulae (I-A) and (I-B), it is preferable that R1 and R2 represent CH₃, C₂H₅, C₃H₇, or C₄H₉. R³ represents preferably CH₂—, —CH₂CH₂—, —CH₂CH₂CH₂—, or —CH₂CH(CH₃)— and more preferably —CH₂CH₂—. p and m represent preferably 1, and p represent more preferably 0. It is preferable that Y represents a single bond. It is preferable that n represents an integer of 1 to 20.

Examples of the non-ionic surfactant include those described in paragraph [0031] of JP2014-104631A, and the content thereof are incorporated in the specification of the present application.

Preferred examples of the non-ionic surfactant include polyoxyethylene aryl ethers and polyoxyethylene-polyoxypropylene block copolymers.

As the non-ionic surfactant, a non-ionic surfactant represented by Formula (II-A) is preferable.

(R⁴)ₛ—Ar³—O(CH₂CH₂O)ₜ(CH₂CH(CH₃)O)ᵤ H (II-A)

In Formula (II-A), R⁴ represents a hydrogen atom or an alkyl group having 1 to 20 carbon atoms, s represents 0, 1, or 2, Ar³ represents an aryl group having 6 to 10 carbon atoms, t and u each represent an integer of 0 to 100, and both t and u do not represent 0 at the same time. In a case where s represents 2, a plurality of R⁴'s may be the same as or different from one another.

Further, organic resin fine particles (for example, microgels) may be used as the hydrophilizing agent.

Microgels are reactive or non-reactive resin particles dispersed in an aqueous medium. It is preferable that the microgels contain a polymerizable group in each particle or on each surface of the particle thereof.

It is preferable that the coating solution that contains a hydrophilizing agent is in the form of an aqueous solution in which the hydrophilizing agent is dissolved or dispersed in a medium mainly formed of water.

The content of the hydrophilizing agent in the coating solution that contains the hydrophilizing agent is preferably in a range of 0.05% to 50% by mass and more preferably in a range of 0.1% to 30% by mass with respect to the total mass of the coating solution.

The viscosity of the coating solution that contains the hydrophilizing agent is preferably in a range of 0.5 to 1000 mPa·s and more preferably in a range of 1 to 100 mPa·s at 25° C.

The surface tension of the coating solution that contains the hydrophilizing agent is preferably in a range of 25 to 70 mN/m and more preferably in a range of 40 to 65 mN/m at 25° C.

The coating solution that contains the hydrophilizing agent may contain an organic solvent, a plasticizer, a preservative, an antifoaming agent, and inorganic salts such as a nitrate and a sulfate.

The coating solution that contains the hydrophilizing agent is applied to the position corresponding to the end portion region in the process of producing the printing plate precursor as described above. It is preferable that the coating width is a region extending to a distance of 5 mm from the end portion or the position corresponding to the end portion.

Examples of the coating method for the coating solution that contains the hydrophilizing agent include a die coating method, a dip coating method, an air knife coating method, a curtain coating method, a roller coating method, a wire bar coating method, a gravure coating method, a slide coating method, an ink jet method, a dispenser method, and a spray method.

As an embodiment in which the region is cut and then coated with the coating solution that contains the hydrophilizing agent, a coating method carried out using a molton roll or cloth impregnated with the coating solution that contains the hydrophilizing agent is exemplified in addition to the above-described coating methods.

After the coating solution that contains the hydrophilizing agent is applied, the coating solution is dried as necessary. The drying temperature is preferably in a range of 60° C. to 250° C. and more preferably in a range of 80° C. to 160° C.

(Undercoat Layer Forming Step)

An undercoat layer forming step is a step of forming the undercoat layer on the aluminum support.

The method of producing the undercoat layer is not particularly limited, and examples thereof include a method of coating the anodized film of the aluminum support with a coating solution for forming an undercoat layer which contains a predetermined compound (such as a compound having a betaine structure).

It is preferable that the coating solution for forming an undercoat layer contains a solvent. Examples of the solvent include water and an organic solvent.

Examples of the method of applying the coating solution for forming an undercoat layer include a bar coater coating method, a rotary coating method, a spray coating method, a curtain coating method, a dip coating method, an air knife coating method, a blade coating method, and a roll coating method.

The coating amount (solid content) of the undercoat layer is preferably in a range of 0.1 to 100 g/m² and more preferably in a range of 1 to 50 g/m².

(Functional Layer Forming Step)

A functional layer forming step is a step of forming the functional layer.

The method of forming the functional layer is not particularly limited, and examples thereof include a method of coating the anodized film or the undercoat layer of the aluminum support with a coating solution for forming a functional layer that contains a predetermined component (such as the infrared absorbing agent, the polymerization initiator, or the polymerizable compound).

It is preferable that the coating solution for forming a functional layer contains a solvent. Examples of the solvent include water and an organic solvent.

Examples of the method of applying the coating solution for forming a functional layer include the methods exemplified as the method of applying the coating solution for forming an undercoat layer.

The coating amount (solid content) of the functional layer varies depending on the purpose thereof, but is typically and preferably in a range of 0.3 to 3.0 g/m².

(Protective Layer Forming Step)

In a case where a protective layer is provided on the functional layer, the method of producing the protective layer is not particularly limited, and examples thereof include a method of coating the functional layer with a coating solution for forming a protective layer which contains a predetermined component.

(Cutting Step)

The cutting can be performed using a known cutting method. Preferred examples thereof include the methods described in JP1996-058257A (JP-H08-058257A), JP1997-211843A (JP-H09-211843A, JP1998-100556A (JP-H10-100556A), and JP1999-052579A (JP-H11-052579A).

In the cutting, the gap between the upper cutting blade and the lower cutting blade, the biting amount, and the blade edge angle of a slitter device used for cutting the printing plate precursor are appropriately adjusted. Particularly, the above-described conditions are appropriately adjusted at the time of formation of the sagging shape.

FIG. 6 is a cross-sectional view illustrating a cutting unit of a slitter device. A pair of cutting blades 40 and 42 are disposed on the slitter device in the lateral direction. The cutting blades 40 and 42 are formed of circular blades on a disk, and upper cutting blades 40a and 40b are coaxially supported by a rotating shaft 44 and lower cutting blades 42a and 42b are coaxially supported by a rotating shaft 46. The upper cutting blades 40a and 40b, and the lower cutting blades 42a and 42b rotate in opposite directions. The printing plate precursor 10c is cut into a predetermined width by passing between the upper cutting blades 40a and 40b and the lower cutting blades 42a and 42b. End portions having a sagging shape can be formed by adjusting the gap between the upper cutting blade 40a and the lower cutting blade 42a and the gap between the upper cutting blade 40b and the lower cutting blade 42b of the cutting unit of the slitter device

### Other Embodiments

In the above-described embodiment, the embodiment in which the micropores 22a in the anodized film 20a have a substantially straight tabular shape has been described, but the micropores may have another structure as long as the average diameter of the micropores in the surface of the anodized film is in a predetermined range.

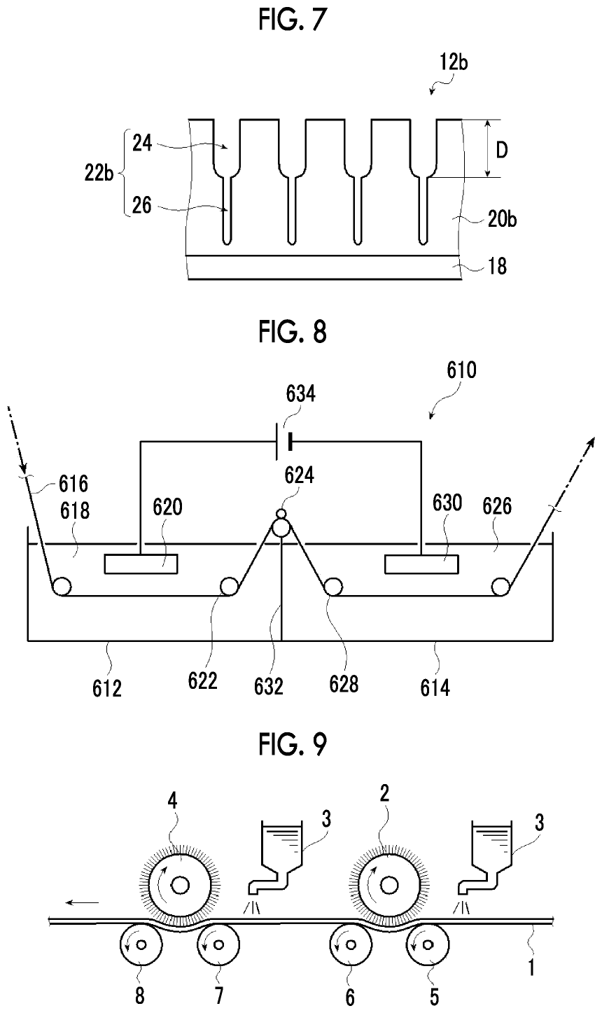

For example, as illustrated in FIG. 7, the aluminum support 12b may include an aluminum plate 18 and an anodized film 20b having micropores 22b formed of large-diameter pores 24 and small-diameter pores 26.

The micropores 22b in the anodized film 20b are formed of large-diameter pores 24 extending to a position at a depth (depth D: see FIG. 7) of 10 to 1000 nm from the surface of the anodized film and small-diameter pores 26 communicating with the bottom of large-diameter pores 24 and extending from a position at a depth of 20 to 2000 nm from the communication position.

Hereinafter, the large-diameter pores 24 and the small-diameter pores 26 will be described in detail.

The average diameter of the large-diameter pores 24 in the surface of the anodized film 20b is preferably in a range of 15 to 100 nm.

The method of measuring the average diameter of the large-diameter pores 24 in the surface of the anodized film 20b is the same as the method of measuring the average diameter of the micropores 22a in the surface of the anodized film 20a.

The bottom of the large-diameter pores 24 is positioned at a depth of 10 to 1000 nm (hereinafter, also referred to as a depth D) from the surface of the anodized film. In other words, the large-diameter pores 24 are pores extending from the surface of the anodized film to a position at a depth of 10 nm to 1000 nm in the depth direction (thickness direction). The depth is preferably in a range of 10 to 200 nm.

Further, the depth thereof is a value obtained by capturing (150000 times) an image of a cross section of the anodized film 20b, measuring the depth of 25 or more large-diameter pores 24, and averaging the obtained values.

The shape of the large-diameter pores 24 is not particularly limited, and examples thereof include a substantially straight tubular shape (substantially cylindrical shape) and a conical shape whose diameter decreases toward the depth direction (thickness direction).

The small-diameter pores 26, as illustrated in FIG. 7, are pores communicating with the bottom of the large-diameter pores 24 and extending from the communication position to the depth direction (thickness direction).

The average diameter of the small-diameter pores 26 in the communication position is preferably 13 nm or less. Further, the average diameter thereof is preferably 11 nm or less and more preferably 10 nm or less. The lower limit thereof is not particularly limited, but is 5 nm or greater in many cases.

The average diameter of small-diameter pores 26 is obtained by observing 4 sheets (N=4) of the surfaces of the anodized film 20a using a FE-SEM at a magnification of 150000, measuring the diameters of micropores (small-diameter pores) present in a range of 400×600 nm² in the obtained four sheets of images, and averaging the values. In a case where the depth of the large-diameter pores is large, the average diameter of small-diameter pores may be acquired by cutting (for example, cutting the upper portion using argon gas) the upper portion (a region where large-diameter pores are present) of the anodized film 20b as necessary and observing the surface of the anodized film 20b using the above-described FE-SEM.

Further, in a case where the shape of the small-diameter pores 26 is not circular, an equivalent circle diameter is used. The “equivalent circle diameter” is a diameter of a circle obtained by assuming the shape of an opening portion of a micropore as a circle having the same projected area as the projected area of the opening portion.

The bottom of the small-diameter pores 26 is in a position extending from the communication position with the large-diameter pores 24 to a depth of 20 to 2000 nm in the depth direction. In other words, the small-diameter pores 26 are pores extending from the communication position with the large-diameter pores 24 to the depth direction (thickness direction), and the depth of the small-diameter pores 26 is in a range of 20 to 2000 nm. Further, the depth is preferably in a range of 500 to 1500 nm.

In addition, the depth thereof is a value obtained by capturing (50000 times) an image of a cross section of the anodized film 20b, measuring the depth of 25 or more small-diameter pores, and averaging the obtained values.

The shape of the small-diameter pores 26 is not particularly limited, and examples thereof include a substantially straight tubular shape (substantially cylindrical shape) and a conical shape whose diameter decreases toward the depth direction. Among these, a substantially straight tubular shape is preferable.

Further, the method of producing the aluminum support 12b is not particularly limited, but a production method of sequentially performing the following steps is preferable.

(Roughening treatment step) A step of performing a roughening treatment on an aluminum plate

(First anodization treatment step) A step of anodizing the aluminum plate which has been subjected to the roughening treatment

(Pore widening treatment step) A step of widening the diameter of micropores in the anodized film by bringing the aluminum plate having the anodized film obtained in the first anodization treatment step into contact with an acid aqueous solution or an alkali aqueous solution

(Second anodization treatment step) A step of anodizing the aluminum plate obtained by the pore widening treatment step

Hereinafter, the procedures of each step will be described in detail.

<Method of Producing Printing Plate>

Next, a method of producing a printing plate using the printing plate precursor that includes an image recording layer will be described.

The method of producing a printing plate typically includes an exposure step of imagewise-exposing (image-exposing) the printing plate precursor including the image recording layer to form an exposed portion and an unexposed portion, and a step of removing the unexposed portion of the imagewise-exposed printing plate precursor.

More specifically, according to an embodiment of the method of producing a printing plate, a method of producing a printing plate which includes an exposure step of imagewise-exposing (image-exposing) the printing plate precursor including the image recording layer to form an exposed portion and an unexposed portion, and a removal step of removing the unexposed portion of the imagewise-exposed printing plate precursor using a developer with a pH of 2 to 12 is exemplified.

Further, according to another embodiment of the method of producing a printing plate, a method of producing a printing plate which includes a step of imagewise-exposing (image-exposing) the printing plate precursor including the image recording layer to form an exposed portion and an unexposed portion, and an on-press development step of supplying at least any of printing ink or dampening water and removing the unexposed portion of the imagewise-exposed printing plate precursor on a printing press is exemplified.

Hereinafter, these embodiments will be described.

The image exposure of the planographic printing plate precursor can be performed in conformity with an image exposure operation for a typical planographic printing plate precursor.

The image exposure is performed by laser exposure through a transparent original picture having a line image, a halftone image, and the like or by laser beam scanning using digital data. The wavelength of a light source is preferably in a range of 750 to 1,400 nm. In case of the light source having a wavelength of 700 nm to 1,400 nm, the image recording layer including the infrared absorbing agent which is a sensitized coloring matter having absorption at a wavelength range.

As the light source having a wavelength of 750 to 1,400 nm, a solid-state laser or a semiconductor laser that radiates infrared rays is preferable. The output of the infrared laser is preferably 100 mW or greater, the exposure time per one pixel is preferably less than 20 microseconds, and the irradiation energy quantity is preferably in a range of 10 to 300 mJ/cm². For the purpose of reducing the exposure time, it is preferable to use a multi-beam laser device. The exposure mechanism may be any of an internal drum system, an external drum system, and a flat bed system.

The image exposure can be performed using a plate setter according to a conventional method. In a case of the on-press development, the planographic printing plate precursor is mounted on the printing press, and image exposure may be performed on the printing press.

The image-exposed printing plate precursor is subjected to a development treatment according to a system (developer treatment system) of removing the unexposed portion using a developer with a pH of 2 to 12 or a system (on-press development system) of removing the unexposed portion using at least one of printing ink or dampening water on the printing press.

(Developer Treatment System)

In the developer treatment system, the image-exposed printing plate precursor is treated by a developer with a pH of 2 to 14, and the image recording layer of the unexposed portion is removed to produce a printing plate.

As the developer, a developer with a pH of 5 to 10 which contains at least one acid group selected from the group consisting of a phosphoric acid group, a phosphonic acid group, and a phosphinic acid group and a compound (specific compound) containing one or more carboxyl groups is preferable.

In a case where the development is carried out by a treatment manually, a method of allowing sponge or absorbent cotton to sufficiently contain a developer, performing treatment while rubbing the entire printing plate precursor, and sufficiently drying the developer after the treatment is completed is exemplified. In a case of an immersion treatment, for example, a method of immersing the printing plate precursor in a tray, a deep tank, or the like containing a developer therein for approximately 60 seconds, stirring the solution, and sufficiently drying the aqueous solution while rubbing the printing plate precursor with absorbent cotton or sponge is exemplified.

It is preferable that a device capable of simplifying the structure and the steps is used in the development treatment.

In a development treatment of the related art, a protective layer is removed by the pre-water washing step, development is performed using an alkali developer, an alkali is removed by the post-water washing step, the gum treatment is performed by a gum coating step, and drying is performed by a drying step.

In addition, development and gum coating can be simultaneously performed using one liquid. As the gum, a polymer is preferable, and a water-soluble polymer or a surfactant is more preferable.

Further, it is preferable that removal of the protective layer, development, and gum coating are simultaneously performed using one liquid without performing the pre-water washing step. Further, it is preferable that the excessive developer is removed using a squeeze roller after the development and the gum coating and then drying is performed.

The present treatment may be performed according to a method of performing immersion in a developer once or a method of performing immersion twice or more times. Among these, a method of performing immersion in the developer once or twice is preferable.

The immersion may be carried out by passing the exposed printing plate precursor through a developer tank in which the developer is stored or spraying the developer onto the plate surface of the exposed printing plate precursor using a spray or the like.

Further, the development treatment is performed using one liquid (one liquid treatment) even in a case where the printing plate precursor is immersed in the developer twice or more times or in a case where the printing plate precursor is immersed, twice or more times, in the same developer as described above or a developer (fatigue liquid) obtained by dissolving or dispersing components of the image recording layer using the developer and the development treatment.

In the development treatment, it is preferable to use a rubbing member and also preferable that a rubbing member such as a brush is installed in a developing bath which removes a non-image area of the image recording layer.

The development treatment can be performed by immersing the printing plate precursor which has been subjected to the exposure treatment and rubbing the plate surface with brushes or pumping up the treatment liquid added to an external tank using a pump, spraying the developer from a spray nozzle, and rubbing the plate surface with brushes at a temperature of preferably 0° C. to 60° C. and more preferably 15° C. to 40° C., according to a conventional method. These development treatments can be continuously performed plural times. For example, the development treatment can be performed by pumping up the developer added to an external tank using a pump, spraying the developer from a spray nozzle, rubbing the plate surface with brushes, spraying the developer from the spray nozzle again, and rubbing the plate surface with the brushes. In a case where the development treatment is performed using an automatic development device, since the developer becomes fatigued as the treatment amount increases, it is preferable that the treatment capability is recovered using a replenisher or a fresh developer.

The development treatment can also be performed using a gum coater or an automatic development device which has been known to be used for a presensitized (PS) plate and computer-to-plate (CTP) in the related art. In a case where an automatic development device is used, for example, any system from among a system of performing the treatment by pumping the developer added to a developer tank or the developer added to an external tank using a pump and spraying the developer from a spray nozzle, a system of performing the treatment by immersing a printing plate in a tank filled with the developer and transporting the printing plate using a guide roller in the developer, and a so-called disposable treatment system, which is a system of performing the treatment by supplying the substantially unused developer by an amount required for each plate can be employed. In all systems, it is preferable that a rubbing mechanism using brushes or a molleton is provided. For example, commercially available automatic development devices (Clean Out Unit C85/C125, Clean-Out Unit+C85/120, FCF 85V, FCF 125V, FCF News (manufactured by Glunz & Jensen); and Azura CX85, Azura CX125, and Azura CX150 (manufactured by AGFA GRAPHICS) can be used. In addition, a device in which a laser exposure portion and an automatic development device portion are integrally incorporated can also be used.

(On-Press Development System)

In the on-press development system, printing ink and dampening water are supplied on the printing press, and the image recording layer of the non-image area is removed to produce a printing plate using the image-exposed printing plate precursor.

In other words, the printing plate precursor is image-exposed, and the printing plate precursor is directly mounted on the printing press without performing any developer treatment or the printing plate precursor is mounted on the printing press, image-exposed on the printing press, and printed by supplying printing ink and dampening water. At the initial stage of the printing, the image recording layer of the unexposed portion is dissolved or dispersed and removed by the supplied printing ink and/or dampening water in the non-image area, and thus the hydrophilic surface in the removed portion is exposed. In the exposed portion, the image recording layer cured by being exposed forms an oil-based ink receiving portion having a lipophilic surface. Printing ink or dampening water may be initially supplied to the plate surface, but it is preferable that printing ink is supplied thereto from the viewpoint of preventing contamination due to the components of the image recording layer from which dampening water has been removed.

In this manner, the printing plate precursor is subjected to on-press development on the printing press and used for printing multiple sheets. In other words, according to an embodiment of the printing method according to the embodiment of the present invention, a printing method including an exposure step of imagewise-exposing the printing plate precursor to form an exposed portion and an unexposed portion, and a printing step of supplying at least any of printing ink or dampening water and removing the unexposed portion of the imagewise-exposed printing plate precursor on a printing press to perform printing is exemplified.

In the method of producing a printing plate from the printing plate precursor according to the embodiment of the present invention, regardless of the development system, the entire surface of the printing plate precursor may be heated before the image exposure, during the image exposure, or during the time period from the image exposure to the development treatment as necessary.

In a case where the printing plate precursor according to the embodiment of the present invention includes a non-photosensitive layer, the printing plate precursor can be applied as a printing plate dummy plate, and the printing plate precursor may be subjected to the above-described (developer treatment system) or (on-press development system).

### Examples

Hereinafter, the present invention will be described in detail with reference to examples, but the present invention is not limited thereto.

<Production of Aluminum Supports>

An aluminum plate (aluminum alloy plate) formed of the material 1S having a thickness of 0.3 mm was subjected to any of the following treatments (A) to (D), thereby producing an aluminum support. Moreover, during all treatment steps, a washing treatment was performed, and liquid cutting was performed using a nip roller after the washing treatment.

<Treatment A>

(A-a) Alkali Etching Treatment

An aluminum plate was subjected to an etching treatment by spraying a caustic soda aqueous solution in which the concentration of caustic soda was 26% by mass and the concentration of aluminum ions was 6.5% by mass using a spray at a temperature of 70° C. Thereafter, the aluminum plate was washed with water using a spray. The amount of aluminum to be dissolved in the surface to be subsequently subjected to an electrochemical roughening treatment was 5 g/m².

(A-b) Desmutting Treatment Using Acidic Aqueous Solution

Next, a desmutting treatment was performed using an acidic aqueous solution. Specifically, the desmutting treatment was performed by spraying the acidic aqueous solution to the aluminum plate for 3 seconds using a spray. As the acidic aqueous solution used for the desmutting treatment, an aqueous solution having a sulfuric acid concentration of 150 g/L was used. The liquid temperature was 30° C.

(A-c) Electrochemical Roughening Treatment Using Hydrochloric Acid Aqueous Solution

Next, an electrochemical roughening treatment was performed using the AC current and an electrolytic solution having a hydrochloric acid concentration of 14 g/L, an aluminum ion concentration of 13 g/L, and a sulfuric acid concentration of 3 g/L. The liquid temperature of the electrolytic solution was 30° C. The aluminum ion concentration was adjusted by adding aluminum chloride.

The waveform of the AC current was a sine wave in which the positive and negative waveforms were symmetrical, the frequency was 50 Hz, the ratio between the anodic reaction time and the cathodic reaction time in one cycle of the AC current was 1:1, and the current density was 75 A/dm² in terms of the peak current value of the AC current waveform. Further, the total electric quantity of the aluminum plate used for the anodic reaction was 450 C/dm², and the electrolytic treatment was performed four times at energization intervals of 4 seconds for each of the electric quantity of 112.5 C/dm². A carbon electrode was used as a counter electrode of the aluminum plate. Thereafter, a washing treatment was performed.

(A-d) Alkali Etching Treatment

The aluminum plate after being subjected to the electrochemical roughening treatment was subjected to an etching treatment by spraying a caustic soda aqueous solution in which the concentration of caustic soda was 5% by mass and the concentration of aluminum ions was 0.5% by mass using a spray at a temperature of 45° C. Thereafter, the aluminum plate was washed with water using a spray. The amount of aluminum to be dissolved in the surface after being subjected to the electrochemical roughening treatment was 0.2 g/m².

(A-e) Desmutting Treatment Using Acidic Aqueous Solution

Next, a desmutting treatment was performed using an acidic aqueous solution. Specifically, the desmutting treatment was performed by spraying the acidic aqueous solution to the aluminum plate for 3 seconds using a spray. As the acidic aqueous solution used for the desmutting treatment, a waste liquid generated in the anodization treatment step (an aqueous solution having a sulfuric acid concentration of 170 g/L and an aluminum ion concentration of 5 g/L) was used. The liquid temperature was 30° C.

(A-f) Anodization Treatment

An anodization treatment was performed with an anodizing device using DC electrolysis illustrated in FIG. 8. An anodized film having a predetermined coated film amount was formed by performing an anodization treatment under conditions in the columns of “first anodization treatment” listed in Table 1. An aluminum plate 616 in an anodization treatment device 610 is transported as indicated by the arrow in FIG. 8. The aluminum plate 616 is positively (+) charged by a power supply electrode 620 in a power supply tank 612 in which an electrolytic solution 618 is stored. Further, the aluminum plate 616 is transported upward by a roller 622 in the power supply tank 612, redirected downward by a nip roller 624, transported toward an electrolytic treatment tank 614 in which an electrolytic solution 626 was stored, and redirected to the horizontal direction by a roller 628. Next, the aluminum plate 616 is negatively (−) charged by an electrolytic electrode 630 so that an anodized film is formed on the surface thereof, and the aluminum plate 616 coming out of the electrolytic treatment tank 614 is transported to the next step. In the anodization treatment device 610, direction changing means is formed of the roller 622, the nip roller 624, and the roller 628. The aluminum plate 616 is transported in a mountain shape and an inverted U shape by the roller 622, the nip roller 624, and the roller 628 in an inter-tank portion between the power supply tank 612 and the electrolytic treatment tank 614. The power supply electrode 620 and the electrolytic electrode 630 are connected to a DC power source 634.

(A-g) Pore Widening Treatment

The aluminum plate after being subjected to the anodization treatment was subjected to a pore widening treatment by being immersed in a caustic soda aqueous solution in which the concentration of caustic soda was 5% by mass and the concentration of aluminum ions was 0.5% by mass at a temperature listed in Table 1 under a time condition listed in Table 1. Thereafter, the aluminum plate was washed with water using a spray.

<Treatment (B)>

(B-a) Alkali Etching Treatment

An aluminum plate was subjected to an etching treatment by spraying a caustic soda aqueous solution in which the concentration of caustic soda was 26% by mass and the concentration of aluminum ions was 6.5% by mass using a spray at a temperature of 70° C. Thereafter, the aluminum plate was washed with water using a spray. The amount of aluminum to be dissolved in the surface to be subsequently subjected to an electrochemical roughening treatment was 5 g/m².

(B-b) Desmutting Treatment Using Acidic Aqueous Solution

Next, a desmutting treatment was performed using an acidic aqueous solution. Specifically, the desmutting treatment was performed by spraying the acidic aqueous solution to the aluminum plate for 3 seconds using a spray. As the acidic aqueous solution used for the desmutting treatment, an aqueous solution having a sulfuric acid concentration of 150 g/L was used. The liquid temperature was 30° C.

(B-c) Electrochemical Roughening Treatment Using Hydrochloric Acid Aqueous Solution

Next, an electrochemical roughening treatment was performed using the AC current and an electrolytic solution having a hydrochloric acid concentration of 14 g/L, an aluminum ion concentration of 13 g/L, and a sulfuric acid concentration of 3 g/L. The liquid temperature of the electrolytic solution was 30° C. The aluminum ion concentration was adjusted by adding aluminum chloride.

The waveform of the AC current was a sine wave in which the positive and negative waveforms were symmetrical, the frequency was 50 Hz, the ratio between the anodic reaction time and the cathodic reaction time in one cycle of the AC current was 1:1, and the current density was 75 A/dm² in terms of the peak current value of the AC current waveform. Further, the total electric quantity of the aluminum plate used for the anodic reaction was 450 C/dm², and the electrolytic treatment was performed four times at energization intervals of 4 seconds for each of the electric quantity of 112.5 C/dm². A carbon electrode was used as a counter electrode of the aluminum plate. Thereafter, a washing treatment was performed.

(B-d) Alkali Etching Treatment

The aluminum plate after being subjected to the electrochemical roughening treatment was subjected to an etching treatment by spraying a caustic soda aqueous solution in which the concentration of caustic soda was 5% by mass and the concentration of aluminum ions was 0.5% by mass using a spray at a temperature of 45° C. Thereafter, the aluminum plate was washed with water using a spray. The amount of aluminum to be dissolved in the surface after being subjected to the electrochemical roughening treatment was 0.2 g/m².

(B-e) Desmutting Treatment Using Acidic Aqueous Solution

Next, a desmutting treatment was performed using an acidic aqueous solution. Specifically, the desmutting treatment was performed by spraying the acidic aqueous solution to the aluminum plate for 3 seconds using a spray. As the acidic aqueous solution used for the desmutting treatment, a waste liquid generated in the anodization treatment step (an aqueous solution having a sulfuric acid concentration of 170 g/L and an aluminum ion concentration of 5 g/L) was used. The liquid temperature was 30° C.

(B-f) First Stage Anodization Treatment

A first stage anodization treatment was performed with an anodizing device using DC electrolysis and having a structure illustrated in FIG. 8. An anodized film having a predetermined coated film amount was formed by performing an anodization treatment under conditions in the columns of “first anodization treatment” listed in Table 1.

(B-g) Pore Widening Treatment

The aluminum plate after being subjected to the anodization treatment was subjected to a pore widening treatment by being immersed in a caustic soda aqueous solution in which the concentration of caustic soda was 5% by mass and the concentration of aluminum ions was 0.5% by mass at a temperature of 40° C. under a time condition listed in Table 1. Thereafter, the aluminum plate was washed with water using a spray.

(B-h) Second Stage Anodization Treatment

A second stage anodization treatment was performed with an anodizing device using DC electrolysis and having a structure illustrated in FIG. 8. An anodized film having a predetermined coated film amount was formed by performing an anodization treatment under conditions in the columns of “second anodization treatment” listed in Table 1.

<Treatment C>

(C-a) Alkali Etching Treatment

An aluminum plate was subjected to an etching treatment by spraying a caustic soda aqueous solution in which the concentration of caustic soda was 25% by mass and the concentration of aluminum ions was 100% by mass using a spray at a temperature of 60° C. The amount of aluminum to be dissolved in the surface to be subsequently subjected to an electrochemical roughening treatment was 3 g/m².

(C-b) Desmutting Treatment Using Acidic Aqueous Solution

Next, a desmutting treatment was performed using an acidic aqueous solution. Specifically, the desmutting treatment was performed by spraying the acidic aqueous solution to the aluminum plate for 5 seconds using a spray. As the acidic aqueous solution used for the desmutting treatment, an aqueous solution having a sulfuric acid concentration of 300 g/L was used. The liquid temperature was 35° C.

(C-c) Electrochemical Roughening Treatment Using Hydrochloric Acid Aqueous Solution

An electrochemical roughening treatment was performed on the aluminum plate using an electrolytic solution (liquid temperature of 35° C.) obtained by dissolving aluminum chloride in a 1 mass % hydrochloric acid aqueous solution and adjusting the aluminum ion concentration to 4.5 g/L. During the electrochemical roughening treatment, a 60 Hz AC power source and a flat cell type electrolytic cell were used. A sine wave was used as the waveform of the AC power source.

In the electrochemical roughening treatment, the current density of the aluminum plate during the anodic reaction at the peak of the alternating current was 30 A/dm². The ratio between the total electric quantity during the anodic reaction and the total electric quantity during the cathodic reaction of the aluminum plate was 0.95. The electric quantity was set to 480 C/dm² in terms of the total electric quantity during the anodic reaction of the aluminum plate. The electrolytic solution was circulated using a pump so that the stirring inside the electrolytic cell was performed.

(C-d) Alkali Etching Treatment

The aluminum plate after the electrochemical roughening treatment was subjected to an etching treatment by spraying a caustic soda aqueous solution at a temperature of 35° C. in which the concentration of caustic soda was 5% by mass and the concentration of aluminum ions was 5 g/L using a spray tube. The amount of aluminum to be dissolved in the surface after being subjected to the electrochemical roughening treatment was 0.05 g/m².

(C-e) Desmutting Treatment Using Acidic Aqueous Solution

Next, a desmutting treatment was performed using an acidic aqueous solution. Specifically, the desmutting treatment was performed by spraying the acidic aqueous solution to the aluminum plate for 5 seconds using a spray. As the acidic aqueous solution used for the desmutting treatment, an aqueous solution having a sulfuric acid concentration of 300 g/L and an aluminum ion concentration of 5 g/L was used. The liquid temperature was 35° C.

(C-f) Anodization Treatment

The aluminum plate on which the roughening treatment had been performed was subjected to an anodization treatment at a treatment temperature of 38° C. and a current density of 15 A/dm² using a phosphoric acid aqueous solution (phosphoric acid concentration of 220 g/L) as an electrolytic solution.

Thereafter, the aluminum plate was washed with water using a spray. The final amount of the oxide film was 1.5 g/m².

<Treatment D>

(D-a) Mechanical Roughening Treatment (Brush Grain Method)

While supplying a suspension of pumice (specific gravity of 1.1 g/cm³) to the surface of an aluminum plate as a polishing slurry liquid using a device illustrated in FIG. 9, a mechanical roughening treatment was performed using rotating bundle bristle brushes. In FIG. 9, the reference numeral 1 represents an aluminum plate, the reference numerals 2 and 4 represent roller-like brushes (in the present examples, bundle bristle brushes), the reference numeral 3 represents a polishing slurry liquid, and the reference numerals 5, 6, 7, and 8 represent a support roller.

The mechanical roughening treatment is performed under conditions in which the median diameter (μm) of a polishing material was 30 μm, the number of the brushes was four, and the rotation speed (rpm) of the brushes was set to 250 rpm. The material of the bundle bristle brushes was nylon 6.10, the diameter of the brush bristles was 0.3 mm, and the bristle length was 50 mm. The brushes were produced by implanting bristles densely into the holes in a stainless steel cylinder having a diameter of 300 mm. The distance between two support rollers (a diameter of 200 mm) of the lower portion of the bundle bristle brush was 300 mm. The bundle bristle brushes were pressed until the load of a driving motor for rotating the brushes became 10 kW plus with respect to the load before the bundle bristle brushes were pressed against the aluminum plate. The rotation direction of the brushes was the same as the moving direction of the aluminum plate.

(D-b) Alkali Etching Treatment

An aluminum plate was subjected to an etching treatment by spraying a caustic soda aqueous solution in which the concentration of caustic soda was 26% by mass and the concentration of aluminum ions was 6.5% by mass using a spray at a temperature of 70° C. Thereafter, the aluminum plate was washed with water using a spray. The amount of aluminum to be dissolved in the surface to be subsequently subjected to an electrochemical roughening treatment was 10 g/m².

(D-c) Desmutting Treatment Using Acidic Aqueous Solution

Next, a desmutting treatment was performed using an acidic aqueous solution. Specifically, the desmutting treatment was performed by spraying the acidic aqueous solution to the aluminum plate for 3 seconds using a spray. As the acidic aqueous solution used for the desmutting treatment, a waste liquid of nitric acid used for the subsequent electrochemical roughening treatment step was used. The liquid temperature was 35° C.

(D-d) Electrochemical Roughening Treatment Using Nitric Acid Aqueous Solution

An electrochemical roughening treatment was continuously performed using an AC voltage of 60 Hz in nitric acid electrolysis. As an electrolytic solution at this time, an electrolytic solution which had been adjusted to have a concentration of aluminum ions of 4.5 g/L by adding aluminum nitrate to a nitric acid aqueous solution having a concentration of 10.4 g/L at a liquid temperature of 35° C. was used. The AC power source waveform is a waveform illustrated in FIG. 4. Further, using a trapezoidal rectangular waveform AC having a time tp, until the current value reached a peak from zero, of 0.8 msec and the duty ratio of 1:1 as the AC power source waveform, the electrochemical roughening treatment was performed using a carbon electrode as a counter electrode. As an auxiliary anode, ferrite was used. An electrolytic cell illustrated in FIG. 5 was used as the electrolytic cell. The current density was 30 A/dm² in terms of the peak current value, and 5% of the current from the power source was separately flowed to the auxiliary anode. The electric quantity (C/dm²) was 185 C/dm² as the total electric quantity at the time of anodization of the aluminum plate.

(D-e) Alkali Etching Treatment

The aluminum plate obtained in the above-described manner was subjected to an etching treatment by spraying a caustic soda aqueous solution in which the concentration of caustic soda was 27% by mass and the concentration of aluminum ions was 2.5% by mass using a spray tube at a temperature of 50° C. Thereafter, the aluminum plate was washed with water using a spray. The amount of aluminum dissolved was 3.5 g/m².

(D-f) Desmutting Treatment Using Acidic Aqueous Solution

Next, a desmutting treatment was performed using a sulfuric acid aqueous solution. Specifically, the desmutting treatment was performed by spraying the sulfuric acid aqueous solution to the aluminum plate for 3 seconds using a spray. As the sulfuric acid aqueous solution used for the desmutting treatment, an aqueous solution having a sulfuric acid concentration of 170 g/L and an aluminum ion concentration of 5 g/L was used. The liquid temperature was 30° C.

(D-g) Electrochemical Roughening Treatment Using Hydrochloric Acid Aqueous Solution

An electrochemical roughening treatment was continuously performed using an AC voltage of 60 Hz in hydrochloric acid electrolysis. As an electrolytic solution, an electrolytic solution which had been adjusted to have a concentration of aluminum ions of 4.5 g/L by adding aluminum chloride to an aqueous solution having 6.2 g/L of hydrochloric acid at a liquid temperature of 35° C. was used. The AC power source waveform is a waveform illustrated in FIG. 4. Further, using a trapezoidal rectangular waveform AC having a time tp, until the current value reached a peak from zero, of 0.8 msec and the duty ratio of 1:1 as the AC power source waveform, the electrochemical roughening treatment was performed using a carbon electrode as a counter electrode. As an auxiliary anode, ferrite was used. An electrolytic cell illustrated in FIG. 5 was used as the electrolytic cell. The current density was 25 A/dm² in terms of the peak current value, and the electric quantity (C/dm²) in the hydrochloric acid electrolysis was 63 C/dm² as the total electric quantity at the time of anodization of the aluminum plate. Thereafter, washing with water was performed using a spray.

(D-h) Alkali Etching Treatment

The aluminum plate obtained in the above-described manner was subjected to an etching treatment by spraying a caustic soda aqueous solution in which the concentration of caustic soda was 5% by mass and the concentration of aluminum ions was 0.5% by mass using a spray at a temperature of 60° C. Thereafter, the aluminum plate was washed with water using a spray. The amount of aluminum to be dissolved was 0.2 g/m².

(D-i) Desmutting Treatment Using Acidic Aqueous Solution

Next, a desmutting treatment was performed using a sulfuric acid aqueous solution. Specifically, the desmutting treatment was performed by spraying the sulfuric acid aqueous solution to the aluminum plate for 4 seconds using a spray. As the sulfuric acid aqueous solution used for the desmutting treatment, a waste liquid generated in the anodization treatment step (an aqueous solution having a sulfuric acid concentration of 170 g/L and an aluminum ion concentration of 5 g/L) was used. The liquid temperature was 35° C.

(D-j) Anodization Treatment

An anodization treatment was performed with an anodizing device using DC electrolysis and having a structure illustrated in FIG. 8. An anodized film having a predetermined coated film amount was formed by performing an anodization treatment under conditions in the columns of “first anodization treatment” listed in Table 1.

(D-k) Pore Widening Treatment

The aluminum plate after being subjected to the anodization treatment was subjected to a pore widening treatment by being immersed in a caustic soda aqueous solution in which the concentration of caustic soda was 5% by mass and the concentration of aluminum ions was 0.5% by mass at a temperature of 40° C. for 3 seconds. Thereafter, the aluminum plate was washed with water using a spray.

(D-l) Hydrophilization Treatment

In order to ensure hydrophilicity of a non-image area, a silicate treatment was performed by dipping the aluminum plate obtained using 2.5% by mass of a No. 3 sodium silicate aqueous solution at 50° C. for 7 seconds. The adhesion amount of Si was 8.5 mg/m². Thereafter, the aluminum plate was washed with water using a spray.

The average diameters of micropores in each surface of the obtained anodized film opposite to the aluminum plate side are collectively listed in Table 2.

The average diameter of micropores is obtained by observing 4 sheets (N=4) of the surfaces of the anodized film using a FE-SEM at a magnification of 150000, measuring the diameters of micropores present in a range of 400×600 nm² in the obtained four sheets of images, and averaging the values.

Further, in a case where the shape of the micropores is not circular, an equivalent circle diameter is used. The “equivalent circle diameter” is a diameter of a circle obtained by assuming the shape of an opening portion of a micropore as a circle having the same projected area as the projected area of the opening portion.

Further, the depths of the micropores in the anodized films obtained in Examples 1 to 34 were in a range of 10 to 3000 nm.

Further, in Example 21, the average diameter of the large-diameter pores in the anodized film having micropores after the second anodization treatment step in the surface of the anodized film, the average diameter of the small-diameter pores in the communication position, and the depths of the large-diameter pores and the small-diameter pores are as follows.

Average diameter of large-diameter pores: 30 nm

Depth of large-diameter pores: 100 nm

Average diameter of small-diameter pores: 8 nm

Depth of small-diameter pores: 900 nm

The average diameter of micropores (average diameter of the large-diameter pores and the small-diameter pores) is a value obtained by observing 4 sheets (N=4) of the surfaces of the large-diameter pores and the surfaces of the small-diameter pores using a FE-SEM at a magnification of 150,000, measuring the diameters of micropores (the large-diameter pores and the small-diameter pores) present in a range of 400×600 nm² in the obtained four sheets of images, and averaging the values.

Further, the depth of the micropores (depth of the large-diameter pores and the small-diameter pores) is a value obtained by observing the cross section of the support (anodized film) using a FE-SEM (at a magnification of 15,000 in observation of the depth of the large-diameter pores and at a magnification of 50,000 in observation of the depth of the small-diameter pores), measuring 25 cases of depths of optional micropores in the obtained image, and averaging the values.

Further, in Example 22, the maximum diameter inside the obtained micropore was 100 nm.

<Undercoat Layer Forming Treatment>

As listed in Table 1, the surface of the anodized film of the aluminum support produced by the above-described treatment in each example and each comparative example was subjected to any of the treatments A to C.

(Treatment A)

The aluminum support was coated with a coating solution 1 for forming an undercoat layer such that the dry coating amount thereof was set to 20 mg/m², thereby forming an undercoat layer.

(Coating Solution 1 for Forming Undercoat Layer)
Compound (UC-1) for undercoat layer (the following structure): 0.18 g Hydroxyethyl imino diacetic acid: 0.05 g
Surfactant (EMALEX 710, manufactured by Nihon Emulsion Co., Ltd.): 0.03 g
Water: 28.0 g

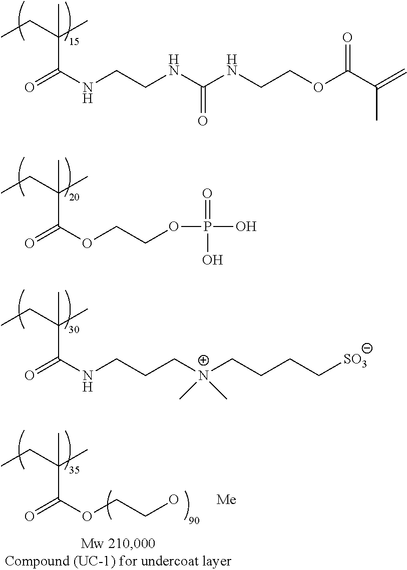

(Treatment B)

The aluminum support was immersed in an aqueous solution (pH of 1.9) containing 4 g/L of polyvinyl phosphonic acid at 40° C. for 10 seconds. Thereafter, the aluminum support was taken out, washed with deionized water containing calcium ions at 20° C. for 2 seconds, and dried. After the treatment, the amount of P and the amount of Ca on the aluminum support were respectively 25 mg/m² and 1.9 mg/m².

(Treatment C)

The aluminum support was coated with a coating solution 2 for forming an undercoat layer such that the dry coating amount thereof was set to 10 mg/m² using a wire bar and dried at 90° C. for 30 seconds, thereby forming an undercoat layer.

(Coating solution 2 for forming undercoat layer)
Polymer compound A (the following structure) (mass average molecular weight: 30000): 0.05 g
Methanol: 27 g
Ion exchange water: 3 g

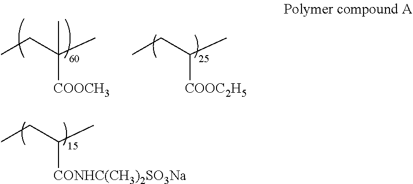

<Formation of Image Recording Layer and Non-Photosensitive Layer>

As listed in Table 1, any of the image recording layers A to C and E and the non-photosensitive layer D were formed on the aluminum support on which the <undercoat layer forming treatment> had been performed, in each example and each comparative example.

The method of forming each image recording layer is as follows.

(Method of Forming Image Recording Layer A)

The aluminum support was bar-coated with a coating solution A for forming an image recording layer with the following composition and dried in an oven at 70° C. for 60 seconds, thereby forming an image recording layer A having a dry coating amount of 0.6 g/m².

(Coating Solution A for Forming Image Recording Layer)
Polymer particle aqueous dispersion liquid (shown below): 20.0 g
Infrared absorbing agent (2) (the following structure): 0.2 g
Polymerization initiator (Irgacure 250, manufactured by Ciba Speciality Chemicals K. K.): 0.4 g
Polymerization initiator (2) (the following structure): 0.15 g
Polymerizable compound SR-399 (manufactured by Sartomer Japan Inc.): 1.50 g
Mercapto-3-triazole: 0.2 g
Byk 336 (manufactured by BYK Chemie GmbH): 0.4 g
Klucel M (manufactured by Hercules, Inc.): 4.8 g
ELVACITE 4026 (manufactured by Ineos Acrylics Ltd.): 2.5 g
Anionic surfactant 1 (the following structure): 0.15 g
n-Propanol: 55.0 g
2-Butanone: 17.0 g

The compounds described with the trade names in the composition above are as follows.
IRGACURE 250: (4-methylphenyl)[4-(2-methylpropyl)phenyl]iodonium=hexafluorophosphate (75 mass % propylene carbonate solution)
SR-399: dipentaerythritolpentaacrylate
Byk336: modified dimethyl polysiloxane copolymer (25 mass % xylene/methoxy propyl acetate solution)
Klucel M: hydroxypropyl cellulose (2 mass % aqueous solution)
ELVACITE 4026: highly branched polymethyl methacrylate (10 mass % 2-butanone solution)

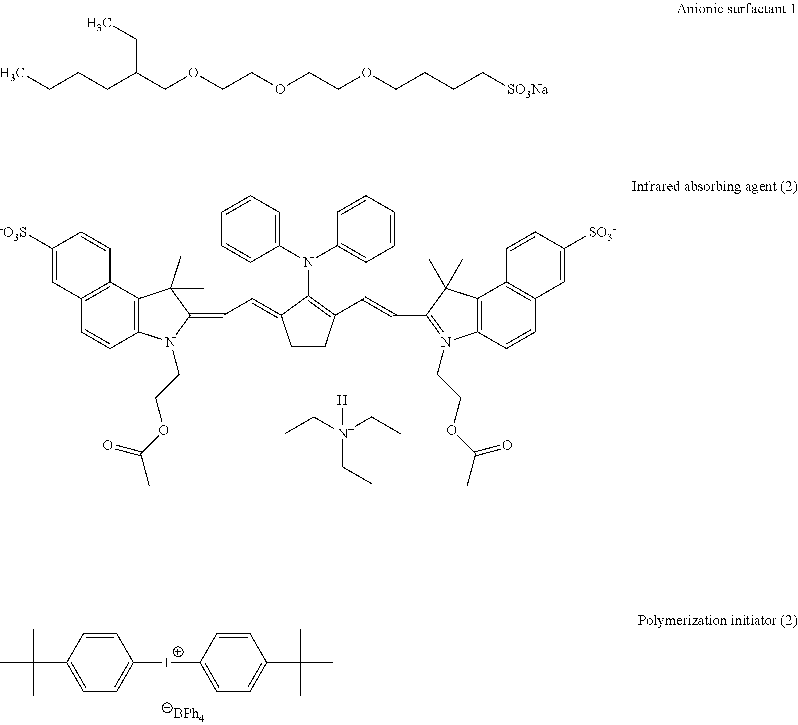

(Preparation of Polymer Particle Aqueous Dispersion Liquid)

Nitrogen gas was introduced into a 1000 ml four-neck flask equipped with a stirrer, a thermometer, a dropping funnel, a nitrogen introduction pipe, and a reflux condenser, deoxygenation was performed, polyethylene glycol methyl ether methacrylate (PEGMA, average number of repeating units of ethylene glycol: 20) (10 g), distilled water (200 g), and n-propanol (200 g) were added to the flask, and then the mixture was heated until the internal temperature thereof was set to 70° C.

Next, a mixture of styrene (St) (10 g), acrylonitrile (AN) (80 g), and 2,2′-azobisisobutyronitrile (0.8 g) prepared in advance was added dropwise for 1 hour. After dropwise addition was finished, the reaction was allowed to be continued for 5 hours, 2,2′-azobisisobutyronitrile (0.4 g) was further added to the flask, and the mixture was heated until the internal temperature was set to 80° C. Subsequently, 2,2′-azobisisobutyronitrile (0.5 g) was added thereto for 6 hours. The total degree of polymerization at the stage of the continued reaction for 20 hours was 98% or greater, and a thermoplastic polymer particle aqueous dispersion liquid having PEGMA, St, and AN at a mass ratio of 10/10/80 was obtained. The particle size distribution of the polymer particle has a maximum value at 150 nm of the volume average particle diameter.

Here, the particle size distribution was acquired by imaging an electron micrograph of polymer particles, measuring the total number of 5,000 particle diameters of polymer particles on the photograph, dividing the interval from the maximum value of the obtained measured value of the particle diameter to 0 into the logarithmic scale of 50, and plotting the appearance frequency of each particle diameter. Further, the particle diameter of a spherical particle having the same particle area as the particle area on the photograph was set to the particle diameter, as non-spherical particles.

(Method of Forming Image Recording Layer B)

The aluminum support was coated with a coating solution B for forming an image recording layer with the following composition and dried at 50° C. for 60 seconds, thereby forming an image recording layer B.

The coating solution B for forming an image recording layer contained thermoplastic polymer particles, an infrared absorbing agent IR-01, and polyacrylic acid, and the pH thereof was 3.6.

Thermoplastic polymer particles: styrene/acrylonitrile copolymer (molar ratio of 50/50, Tg of 99° C., volume average particle diameter of 60 nm)

Infrared absorbing agent IR-01: infrared absorbing agent with the following structure

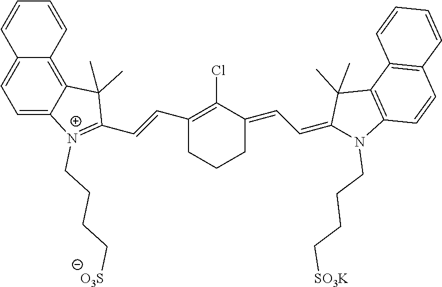

Polyacrylic acid: weight-average molecular weight of 250000

Further, the coating amount of each component was as follows.
Thermoplastic polymer particles: 0.7 (g/m²)
Infrared absorbing agent IR-01: 1.20×10⁻⁴ (mol/m²)
Polyacrylic acid: 0.09 (g/m²)

(Method of Forming Image Recording Layer C)

The aluminum support was bar-coated with a coating solution C for forming an image recording layer with the following composition and dried in an oven at 100° C. for 60 seconds, thereby forming an image recording layer C having a dry coating amount of 1.0 g/m².

The coating solution C for forming an image recording layer was obtained by mixing a photosensitive solution (1) and a microgel solution (1) described below immediately before the coating and then stirring the solution.

(Photosensitive Solution (1))
Binder polymer (1) (the following structure, Mw: 55,000 and n (number of ethylene oxide (EO) repeating units): 2): 0.240 parts by mass
Infrared absorbing agent (1) (the following structure): 0.020 parts by mass
Borate compound (sodium tetraphenyl borate): 0.010 parts by mass
Polymerization initiator (1) (the following structure): 0.162 parts by mass
Polymerizable compound (tris(acryloyloxyethyl) isocyanurate, NK ESTER A-9300, manufactured by Shin-Nakamura Chemical Co., Ltd.): 0.192 parts by mass
Anionic surfactant 1 (the structure shown above): 0.050 parts by mass
Fluorine-based surfactant (1) (the following structure): 0.008 parts by mass
2-Butanone: 1.091 parts by mass
1-Methoxy-2-propanol: 8.609 parts by mass

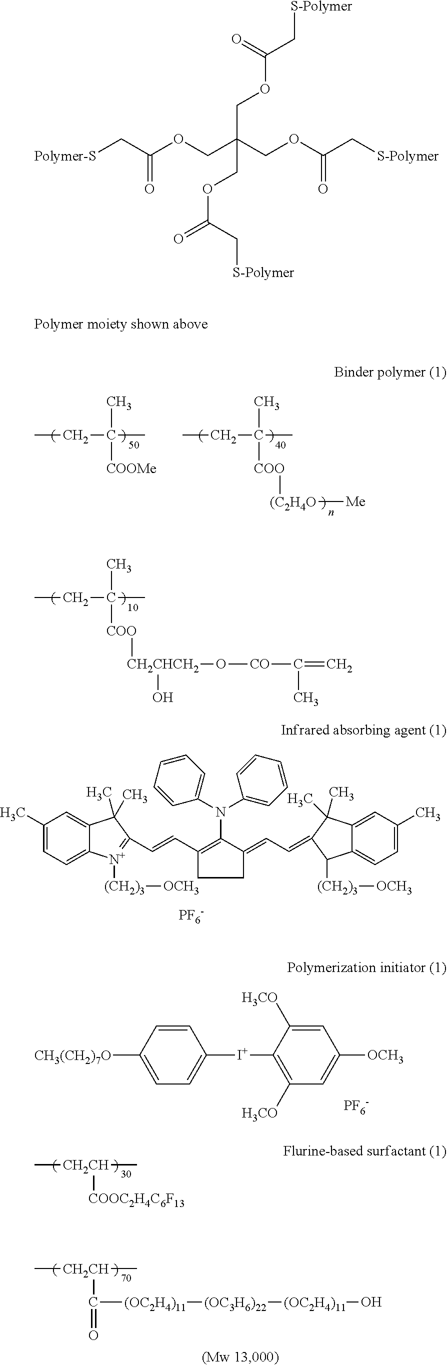

(Microgel Solution (1))

A method of preparing a microgel solution (1) is described below.

Bismuth tris(2-ethylhexanoate) (NEOSTANN U-600 (manufactured by NITTO KASEI CO., LTD.)) (0.043 parts by mass) was added to an ethyl acetate (25.31 parts by mass) suspension solution of isophorone diisocyanate (17.78 parts by mass, 80 molar equivalents) and the following polyhydric phenol compound (1) (7.35 parts by mass, 20 molar equivalents) and the solution was stirred. The reaction temperature was set to 50° C. at the time of heat generation being subsided, and the solution was stirred for 3 hours, thereby obtaining an ethyl acetate solution (50% by mass) solution of a polyvalent isocyanate compound (1).

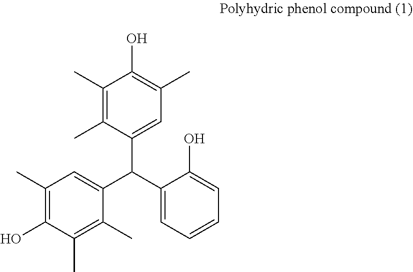 [SMILES: Cc1cc(C(c2ccccc2O)c2cc(C)c(O)c(C)c2C)c(C)c(C)c1O]

The following oil phase components and the water phase components were mixed with each other and emulsified at 12,000 rpm for 10 minutes using a homogenizer.

The obtained emulsion was stirred at 45° C. for 4 hours, a 10 mass % aqueous solution (5.20 parts by mass) of 1,8-diazabicyclo[5.4.0]undeca-7-ene-octylate (U-CAT SA102, manufactured by San-Apro Ltd.) was added thereto, and the solution was stirred at room temperature for 30 minutes and allowed to stand at 45° C. for 24 hours. The concentration of solid contents was adjusted to 20% by mass using distilled water, thereby obtaining the microgel solution (1). The volume average particle diameter was measured using a dynamic light scattering type particle size distribution measuring device LB-500 (manufactured by Horiba Ltd.) according to a light scattering method, and the value was 0.28 μm.

(Oil Phase Components)

(Component 1) ethyl acetate: 12.0 parts by mass

(Component 2) adduct (50 mass % ethyl acetate solution, manufactured by Mitsui Chemicals, Inc.) obtained by adding trimethylolpropane (6 mol) and xylene diisocyanate (18 mol) and adding methyl one-terminal polyoxyethylene (1 mol, repetition number of oxyethylene units: 90) thereto: 3.76 parts by mass

(Component 3) polyvalent isocyanate compound (1) (as 50 mass % ethyl acetate solution): 15.0 parts by mass

(Component 4) 65 mass % solution of dipentaerythritol pentaacrylate (SR-399, manufactured by Sartomer Japan Inc.) in ethyl acetate: 11.54 parts by mass

(Component 5) 10% solution of sulfonate type surfactant (PIONINE A-41-C, manufactured by TAKEMOTO OIL & FAT Co., Ltd.) in ethyl acetate: 4.42 parts by mass

(Water Phase Components)

Distilled water: 46.87 parts by mass

(Method of Forming Non-Photosensitive Layer D)

A non-photosensitive layer was formed according to the same procedures as those for the (method of forming the image recording layer C) except that a coating solution D for forming a non-photosensitive layer formed by removing the infrared absorbing agent (1) and the polymerization initiator (1) from the coating solution C for forming an image recording layer was used.

(Method of Forming Image Recording Layer E)

The aluminum support was coated with a coating solution E for forming an image recording layer with the following composition using a wire bar and dried at 115° C. for 34 seconds using a hot air dryer, thereby forming an image recording layer E having a dry coating amount of 1.4 g/m².

(Coating Solution E for Forming Image Recording Layer)
Infrared absorbing agent (IR-1) (the following structure): 0.074 g
Polymerization initiator (OS-12) (the following structure): 0.280 g
Additive (PM-1) (the following structure): 0.151 g
Polymerizable compound (AM-1) (the following structure): 1.00 g
Binder polymer (BT-1) (the following structure): 1.00 g
Ethyl violet (C-1) (the following structure): 0.04 g
Fluorine-based surfactant: 0.015 g
(MEGAFACE F-780-F, manufactured by DIC Corporation, 30 mass % solution of methyl isobutyl ketone)
Methyl ethyl ketone: 10.4 g
Methanol: 4.83 g
1-Methoxy-2-propanol: 10.4 g

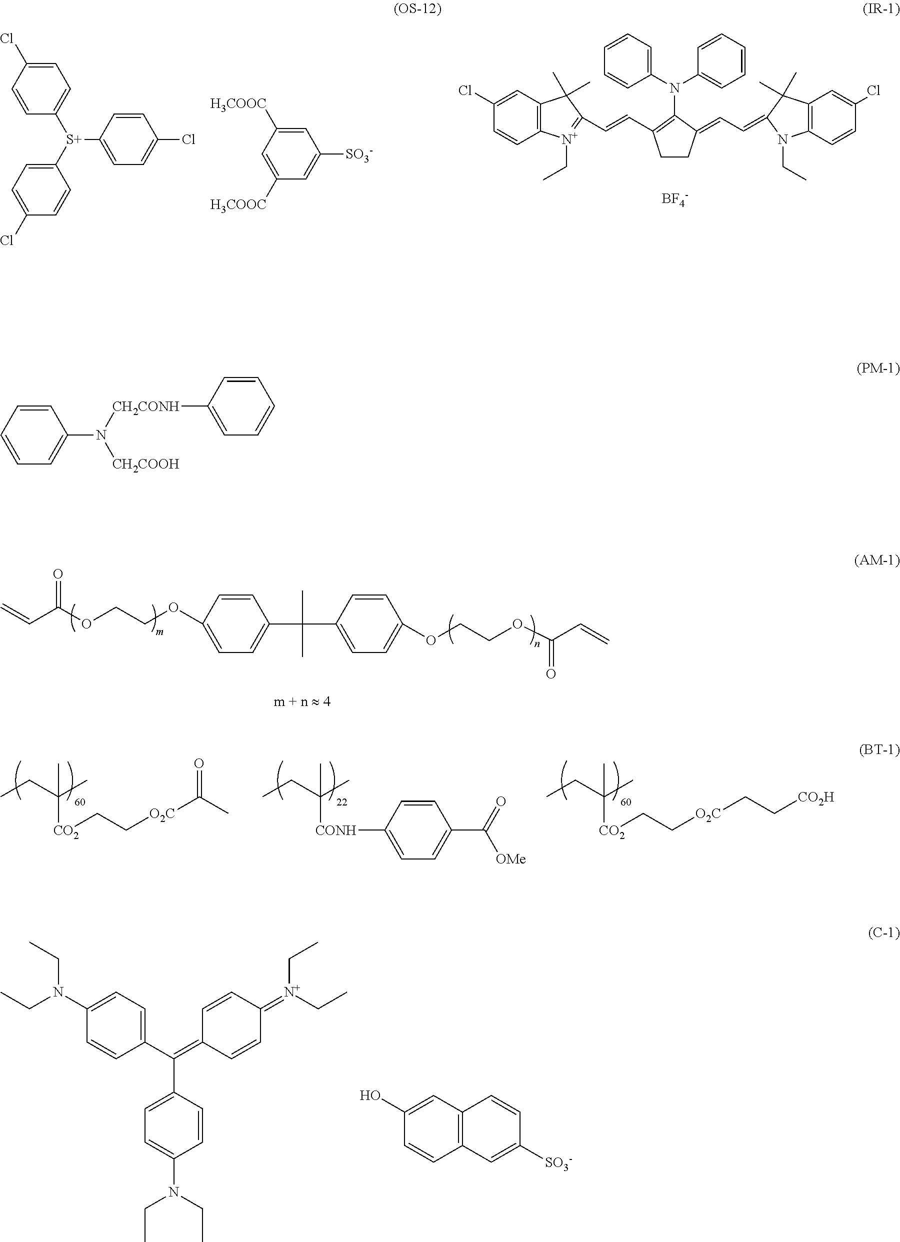

<Formation of Protective Layer>

As listed in Table 1, a protective layer A or a protective layer B was formed on the aluminum support on which the process of <formation of the image recording layer or the non-photosensitive layer> had been performed.

The method of forming each protective layer is as follows.

(Formation of Protective Layer A)

The image recording layer was further coated with a coating solution (1) for forming a protective layer with the following composition using a bar coater and dried in an oven at 120° C. for 60 seconds to form a protective layer having a dry coating amount of 0.15 g/m², thereby preparing a printing plate precursor.

(Coating Solution a for Forming Protective Layer)
Inorganic layered compound dispersion liquid (1): 1.5 g
Hydrophilic polymer (1) (the following structure, Mw: 30000) (solid content): 0.03 g
6 mass % aqueous solution of polyvinyl alcohol (CKS50, sulfonic acid-modified, saponification degree of 99% by mole or greater, degree of polymerization of 300, manufactured by Nippon Synthetic Chemical Industry Co., Ltd.): 0.1 g
6 mass % aqueous solution of polyvinyl alcohol (PVA-405, saponification degree of 81.5% by mole, degree of polymerization of 500, manufactured by KURARAY CO., LTD.): 0.03 g
1 mass % aqueous solution of surfactant (EMALEX 710, the following structure, manufactured by Nihon Emulsion Co., Ltd.): 0.86 g
Ion exchange water: 6.0 g

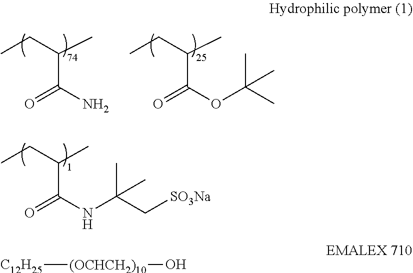

(Preparation of Inorganic Layered Compound Dispersion Liquid (1))

Synthetic mica SOMASIF ME-100 (manufactured by CO—OP CHEMICAL CO., LTD.) (6.4 g) was added to ion exchange water (193.6 g) and dispersed such that the average particle diameter (laser scattering method) was set to 3 μm using a homogenizer. The aspect ratio of the obtained dispersed particles was 100 or greater.

(Formation of Protective Layer B)

The image recording layer was coated with a coating solution B for forming a protective layer with the following composition using a wire bar and dried at 125° C. for 75 seconds using a hot air dryer to form a protective layer having a dry coating amount of 1.6 g/m², thereby preparing a printing plate precursor.

(Coating Solution B for Forming Protective Layer)
Synthetic mica (SOMASIF ME-100, 8% aqueous dispersion liquid, manufactured by CO—OP CHEMICAL CO., LTD.): 94 g
Polyvinyl alcohol (CKS-50, saponification degree of 99% by mole, degree of polymerization of 300, manufactured by Nippon Synthetic Chemical Industry Co., Ltd.): 58 g
Carboxymethyl cellulose (CELLOGEN PR, manufactured by DKS Co., Ltd): 24 g
Surfactant-1 (PLURONIC P-84, manufactured by BASF SE): 2.5 g
Surfactant-2 (EMALEX 710, manufactured by Nihon Emulsion Co., Ltd.): 5 g
Pure water: 1364 g

<Edge Treatment>

As listed in Table 1, any of the coating solutions (hydrophilic coating solutions) A to C containing the hydrophilizing agent shown below was used in each example and each comparative example.

(Hydrophilic Coating Solution A)

2.5% by mass of the compound (Mw: 100000) represented by the following formula and 0.5% by mass of microgel fine particles were added to pure water, and the solution was stirred to prepare a hydrophilic coating solution A.

Further, “15” and “85” in the following formulae represent % by mole of each repeating unit with respect to all repeating units in the compound. Further, M³ and M⁴ represent a hydrogen atom or a sodium atom.

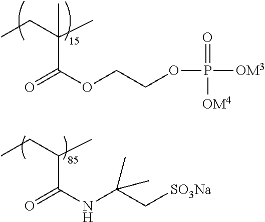

A microgel solution prepared by the following method was used.

An adduct (TAKENATE D-110N, manufactured by Mitsui Chemicals polyurethanes, Inc.) (10 g) of trimethylolpropane and xylene diisocyanate, pentaerythritol triacrylate (SR444, manufactured by Sartomer Japan Inc.) (3.15 g), and an alkylbenzene sulfonate (PIONINE A-41C, manufactured by TAKEMOTO OIL & FAT Co., Ltd.) (0.1 g), as oil phase components, were dissolved in ethyl acetate (17 g). As a water phase component, a 4 mass % aqueous solution of polyvinyl alcohol (PVA-205, manufactured by Kuraray Co., Ltd.) (40 g) was prepared. The oil phase components and the water phase components were mixed with each other and emulsified at 12,000 rpm for 10 minutes using a homogenizer. Distilled water (25 g) was added to the obtained emulsion, and the resultant was stirred at room temperature for 30 minutes and stirred at 50° C. for 3 hours. The microgel solution obtained in this manner was diluted with distilled water such that the concentration of solid contents of the microgel solution was set to 15% by mass, thereby preparing a microgel solution containing microgels. The average particle diameter of the microgels measured by a light scattering method was 0.2 μm.

(Hydrophilic Coating Solution B)

As a hydrophilic coating solution B, a hydrophilic coating solution B described in paragraph [0233] of WO2015/119089A was used.

The hydrophilic coating solution B contained Na 1-naphthalene sulfonate and Na dihydrogen phosphate as hydrophilizing agents.

(Hydrophilic Coating Solution C)

As a hydrophilic coating solution C, a treatment liquid 1 described in paragraph [0173] of JP2011-177983A was used. The hydrophilic coating solution C contained gum Arabic as the hydrophilizing agent.

<Timing of Applying Hydrophilic Coating Solution>

The prepared hydrophilic coating solution was applied at the timing listed in Table 1. Further, 1 to 8 in the columns of “treatment timing” in Table 1 indicate that the treatments were performed according to the following procedures. In the description below, “S1” represents the “undercoat layer forming treatment” described above, “S2” represents the “formation of image recording layer of non-photosensitive layer” described above, and “S3” represents the “formation of protective layer” described above.

“1”: Edge treatment→Si→S2→S3→slit→exposure

“2”: S1→edge treatment→S2→S3→slit→exposure

“3”: S1→S2→edge treatment→S3→slit→exposure

“4”: S1→S2→S3→edge treatment slit→exposure

“5”: S1→S2→S3→slit→edge treatment→exposure

“6”: S1→S2→S3→slit→exposure→edge treatment

“7”: S1→edge treatment→S2→S3→slit

“8”: S1→S2→S3→slit→edge treatment

The hydrophilizing agent was applied to the region of the plate surface on the functional layer side extending to a distance of 5 mm inward from two facing end portions of the printing plate precursor by performing the above-described treatments.

Further, the edge treatment was performed according to the following procedures.

As the coating device, 2NL04 (manufactured by Heishin Ltd.) was used.

In each example and each comparative example, the coating was performed such that the coating amount was set to a predetermined amount of the solid content by adjusting the transport speed with a clearance of 0.3 mm and a liquid supply amount of 5 cc/min.

Further, the slit treatment was performed in the following manner.

The printing plate precursor was cut such that the end portion with the sagging amount and the sagging width listed in Table 1 had a sagging shape by adjusting the gap between the upper cutting blade and the lower cutting blade, the biting amount, and the blade edge angle using a rotary blade as illustrated in FIG. 6. The sagging width thereof was set to 150 μm.

Further, the exposure treatment described in the section of the “evaluation method” described below corresponds to the above-described exposure treatment.

<Evaluation Method>

The prepared printing plate precursors were set by Luxel PLATESETTER T-6000III (manufactured by Fujifilm Corporation) equipped with an infrared semiconductor laser and then exposed under conditions of an external surface drum rotation speed of 1000 rpm, a laser output of 70%, and a resolution of 2400 dpi. A solid image and a 50% halftone dot chart were included in the exposed image.

Here, in the examples in which the image recording layer E was used, the evaluation of the printing plate precursor described below was performed after the development treatment described below was performed.

(Development Treatment)

The image-exposed printing plate precursor was subjected to a development treatment at a development temperature of 30° C. and a transport speed (line speed) of 2 m/min using an automatic development device LP-1310HII (manufactured by Fujifilm Corporation). A 1:4 water diluent of HN-D (manufactured by Fujifilm Corporation) was used as the developer, a 1:1.4 water diluent of HN-DR (manufactured by Fujifilm Corporation) was used as a development replenisher, and a 1:1 water diluent of HN-GV (manufactured by Fujifilm Corporation) was used as a finisher.

(Evaluation of Printing Plate Precursor)

(Evaluation of Edge Stain Resistance)

The printing plate precursors which had been exposed in the above-described manner were mounted on an offset rotary printing press, and printing was performed at a speed of 100,000 sheets/hour using SOIBI KKST-S (red) (manufactured by InkTec Corporation) as printing ink for newspaper and ECO SEVEN N-1 (manufactured by SAKATA INX CORPORATION) as dampening water, the 1000 printed material was sampled, and the degree of linear stains on the end portion (edge portion) was evaluated based on the following standards. At this time, the printing was evaluated under severer conditions than the standard conditions by reducing the amount of dampening water by 30% from the standard amount.

5: Stains were not found from the end portion

4: The level of stains was between 3 and 5

3: The end portion was slightly stained, but it was in an acceptable level

2: The level of stains was between 1 and 3, and it was in an unacceptable level

1: The end portion was clearly stained, and it was in an unacceptable level

(Evaluation of Stains in Setter and Vendor)

Not found: Adhesion of plate material components to a belt for transport and a roller was not found, which was not practically problematic.

Found: Adhesion of plate material components to a belt for transport and a roller was found, which was practically problematic.

(Evaluation of Deinking Capability after being Left to Stand)

The printing plate precursors which had been exposed in the above-described manner were mounted on an offset rotary printing press, and printing was performed at a speed of 100,000 sheets/hour using SOIBI KKST-S(red) (manufactured by InkTec Corporation) as printing ink for newspaper and ECO SEVEN N-1 (manufactured by SAKATA INX CORPORATION) as dampening water, and 30000 sheets were printed. Further, the printing was temporarily stopped, the printing plate was allowed to stand on the printing press for 4 hours in a room at a temperature of 25° C. and a humidity of 50%, and 200 sheets were printed again. The state of stains on the 200-th printing paper was determined based on the following standards.

5: Stains were not found from the end portion

4: The level of stains was between 3 and 5

3: The end portion was slightly stained, but it was in an acceptable level

2: The level of stains was between 1 and 3, and it was in an unacceptable level

1: The end portion was clearly stained, and it was in an unacceptable level

(Evaluation of Printing Durability)

The obtained printing plate precursors were exposed using Luxel PLATESETTER T-6000111 (manufactured by Fujifilm Corporation) equipped with an infrared semiconductor laser under conditions of an external surface drum rotation speed of 1000 rpm, a laser output of 70%, and a resolution of 2,400 dpi. The exposure was carried out such that the exposed image had a solid image and a 50% halftone dot chart of a 20 μm dot frequency modulation (FM) screen.

The obtained exposed printing plate precursor was attached to the plate cylinder of a printing press LITHRONE26 (manufactured by KOMORI Corporation) without performing a development treatment. Dampening water and ink were supplied using a standard automatic printing start method for LITHRONE26 using dampening water, in which the volume ratio of Ecolity-2 (manufactured by Fujifilm Corporation) to tap water was 2:98, and Values-G (N) black ink (manufactured by DIC Corporation) to perform on-press development, and then printing was performed on 100 sheets of Tokubishi Art (76.5 kg) paper at a printing speed of 10000 sheets per hour.

Further, the printing was continued, and the printing durability was evaluated based on the number of printed sheets at the time at which the density of the solid image started to decrease by visual conformation.

The columns of “support” in Table 2 indicate any of the <treatment A> to <treatment D> for producing the aluminum support.

The columns of “average diameter” indicate the average diameter of micropores in the surface of the anodized film.

The columns of “undercoat layer forming treatment” indicate the treatments (treatments A to C) performed in the <undercoat layer forming treatment>.

The columns of “difference in content (mg/m²)” indicate the difference (content A −content B) between the content A of the hydrophilizing agent per unit area in the region of the plate surface on the functional layer side, extending to a distance 5 mm inward from two facing end portions of the printing plate precursor and the content B of the hydrophilizing agent per unit area in the region other than the above-described region.

TABLE 1

| | | | | | | | First anodization treatment | | |
|---|---|---|---|---|---|---|---|---|---|
| | | | | | | | Concentration | Concentration | |
| | Roughening treatment | | | | | | of sulfuric | of phosphoric | |
| | | | | | Hydrochloric | | acid in | acid in | |
| | | Alkali | Nitric acid | Alkali | acid | Alkali | electrolytic | electrolytic | |
| | Brush | etching | electrolysis | etching | electrolysis | etching | solution | solution | Temperature |
| | grain | (g/m²) | (C/dm²) | (g/m²) | (C/dm²) | (g/m²) | (g/L) | (g/L) | (° C.) |
| Example 1 | — | 5 | — | — | 450 | 0.2 | 170 | — | 50 |
| Example 2 | — | 5 | — | — | 450 | 0.2 | 170 | — | 50 |
| Example 3 | — | 5 | — | — | 450 | 0.2 | 170 | — | 50 |
| Example 4 | — | 5 | — | — | 450 | 0.2 | 170 | — | 50 |
| Example 5 | — | 5 | — | — | 450 | 0.2 | 170 | — | 50 |
| Example 6 | — | 5 | — | — | 450 | 0.2 | 170 | — | 50 |
| Example 7 | — | 5 | — | — | 450 | 0.2 | 170 | — | 50 |
| Example 8 | — | 5 | — | — | 450 | 0.2 | 170 | — | 15 |
| Example 9 | — | 5 | — | — | 450 | 0.2 | 170 | — | 15 |
| Example 10 | — | 5 | — | — | 450 | 0.2 | 170 | — | 15 |
| Example 11 | — | 5 | — | — | 450 | 0.2 | 170 | — | 50 |
| Example 12 | — | 5 | — | — | 450 | 0.2 | 170 | — | 50 |
| Example 13 | — | 5 | — | — | 450 | 0.2 | 170 | — | 50 |
| Example 14 | — | 5 | — | — | 450 | 0.2 | 170 | — | 50 |
| Example 15 | — | 5 | — | — | 450 | 0.2 | 170 | — | 50 |
| Example 16 | — | 5 | — | — | 450 | 0.2 | 170 | — | 50 |
| Example 17 | — | 5 | — | — | 450 | 0.2 | 170 | — | 50 |
| Example 18 | — | 5 | — | — | 450 | 0.2 | 170 | — | 50 |
| Example 19 | — | 5 | — | — | 450 | 0.2 | 170 | — | 50 |
| Example 20 | — | 5 | — | — | 450 | 0.2 | 170 | — | 50 |
| Example 21 | — | 5 | — | — | 450 | 0.2 | 170 | — | 50 |
| Example 22 | — | 3 | — | — | 480 | 0.05 | — | 220 | 38 |
| Example 23 | — | 5 | — | — | 450 | 0.2 | 170 | — | 50 |
| Example 24 | Present | 10 | 185 | 3.5 | 63 | 0.2 | 170 | — | 50 |
| Example 25 | Present | 10 | 185 | 3.5 | 63 | 0.2 | 170 | — | 50 |
| Example 26 | Present | 10 | 185 | 3.5 | 63 | 0.2 | 170 | — | 50 |
| Example 27 | Present | 10 | 185 | 3.5 | 63 | 0.2 | 170 | — | 50 |
| Example 28 | Present | 10 | 185 | 3.5 | 63 | 0.2 | 170 | — | 50 |
| Example 29 | Present | 10 | 185 | 3.5 | 63 | 0.2 | 170 | — | 50 |
| Example 30 | Present | 10 | 185 | 3.5 | 63 | 0.2 | 170 | — | 50 |
| Example 31 | Present | 10 | 185 | 3.5 | 63 | 0.2 | 170 | — | 50 |
| Example 32 | Present | 10 | 185 | 3.5 | 63 | 0.2 | 170 | — | 50 |
| Example 33 | Present | 10 | 185 | 3.5 | 63 | 0.2 | 170 | — | 50 |
| Example 34 | — | 5 | — | — | 450 | 0.2 | 170 | — | 50 |
| Comparative | — | 5 | — | — | 450 | 0.2 | 170 | — | 50 |
| Example 1 | | | | | | | | | |
| Comparative | — | 5 | — | — | 450 | 0.2 | 170 | — | 15 |
| Example 2 | | | | | | | | | |
| Comparative | — | 5 | — | — | 450 | 0.2 | 170 | — | 50 |
| Example 3 | | | | | | | | | |

| | | | | | Second anodization treatment | | | |
|---|---|---|---|---|---|---|---|---|
| | | | | | Concentration | | | |
| | | | | | of sulfuric | | | |
| | First anodization treatment | | Pore widening | | acid in | | | |
| | Current | Coating | treatment | | electrolytic | | Current | Coating |
| | density | amount | Temperature | Time | solution | Temperature | density | amount |
| | (A/dm²) | (g/m²) | (° C.) | (sec) | (g/L) | (° C.) | (A/dm²) | (g/m²) |
| Example 1 | 30 | 2.4 | 28 | 3 | — | — | — | — |
| Example 2 | 30 | 2.4 | 32 | 3 | — | — | — | — |
| Example 3 | 30 | 2.4 | 35 | 3 | — | — | — | — |
| Example 4 | 30 | 2.4 | 37 | 3 | — | — | — | — |
| Example 5 | 30 | 2.4 | 40 | 3 | — | — | — | — |
| Example 6 | 30 | 2.4 | 40 | 5 | — | — | — | — |
| Example 7 | 30 | 2.4 | 40 | 7 | — | — | — | — |
| Example 8 | 30 | 2.4 | 40 | 9 | — | — | — | — |
| Example 9 | 40 | 2.4 | 40 | 12 | — | — | — | — |
| Example 10 | 60 | 2.4 | 40 | 15 | — | — | — | — |
| Example 11 | 30 | 2.4 | 40 | 3 | — | — | — | — |
| Example 12 | 30 | 2.4 | 40 | 3 | — | — | — | — |
| Example 13 | 30 | 2.4 | 40 | 3 | — | — | — | — |
| Example 14 | 30 | 2.4 | 40 | 3 | — | — | — | — |
| Example 15 | 30 | 2.4 | 40 | 3 | — | — | — | — |
| Example 16 | 30 | 2.4 | 40 | 3 | — | — | — | — |
| Example 17 | 30 | 2.4 | 40 | 3 | — | — | — | — |
| Example 18 | 30 | 2.4 | 40 | 3 | — | — | — | — |
| Example 19 | 30 | 2.4 | 40 | 3 | — | — | — | — |
| Example 20 | 30 | 2.4 | 40 | 3 | — | — | — | — |
| Example 21 | 30 | 0.3 | 40 | 3 | 170 | 50 | 13 | 2.1 |
| Example 22 | 15 | 1.5 | — | — | — | — | — | — |
| Example 23 | 30 | 2.4 | 40 | 3 | — | — | — | — |
| Example 24 | 30 | 2.4 | 40 | 3 | — | — | — | — |
| Example 25 | 30 | 2.4 | 40 | 3 | — | — | — | — |
| Example 26 | 30 | 2.4 | 40 | 3 | — | — | — | — |
| Example 27 | 30 | 2.4 | 40 | 3 | — | — | — | — |
| Example 28 | 30 | 2.4 | 40 | 3 | — | — | — | — |
| Example 29 | 30 | 2.4 | 40 | 3 | — | — | — | — |
| Example 30 | 30 | 2.4 | 40 | 3 | — | — | — | — |
| Example 31 | 30 | 2.4 | 40 | 3 | — | — | — | — |
| Example 32 | 30 | 2.4 | 40 | 3 | — | — | — | — |
| Example 33 | 30 | 2.4 | 40 | 3 | — | — | — | — |
| Example 34 | 30 | 2.4 | 40 | 3 | — | — | — | — |
| Comparative | 30 | 2.4 | 22 | 2 | — | — | — | — |
| Example 1 | | | | | | | | |
| Comparative | 60 | 2.4 | 40 | 18 | — | — | — | — |
| Example 2 | | | | | | | | |
| Comparative | 30 | 2.4 | 40 | 3 | — | — | — | — |
| Example 3 | | | | | | | | |

TABLE 2

| | | | | | | End portion |
|---|---|---|---|---|---|---|
| | Support | | | | | treatment |
| | | Average | | | | Timing |
| | | diameter | Undercoat | Image recording layer or | | for |
| | Support | (nm) | layer | non-photosensitive layer | Protective layer | treatment |
| Example 1 | A | 13 | A | Image recording layer A | — | 2 |
| Example 2 | A | 18 | A | Image recording layer A | — | 2 |
| Example 3 | A | 21 | A | Image recording layer A | — | 2 |
| Example 4 | A | 25 | A | Image recording layer A | — | 2 |
| Example 5 | A | 30 | A | Image recording layer A | — | 2 |
| Example 6 | A | 34 | A | Image recording layer A | — | 2 |
| Example 7 | A | 40 | A | Image recording layer A | — | 2 |
| Example 8 | A | 65 | A | Image recording layer A | — | 2 |
| Example 9 | A | 88 | A | Image recording layer A | — | 2 |
| Example 10 | A | 100 | A | Image recording layer A | — | 2 |
| Example 11 | A | 30 | A | Image recording layer A | — | 2 |
| Example 12 | A | 30 | A | Image recording layer A | — | 2 |
| Example 13 | A | 30 | A | Image recording layer A | — | 2 |
| Example 14 | A | 30 | A | Image recording layer A | — | 1 |
| Example 15 | A | 30 | A | Image recording layer A | — | 3 |
| Example 16 | A | 30 | A | Image recording layer A | — | 4 |
| Example 17 | A | 30 | A | Image recording layer A | — | 5 |
| Example 18 | A | 30 | A | Image recording layer A | — | 6 |
| Example 19 | A | 30 | A | Image recording layer A | — | 5 |
| Example 20 | A | 30 | A | Image recording layer A | — | 5 |
| Example 21 | B | 30 | A | Image recording layer A | — | 2 |
| Example 22 | C | 30 | A | Image recording layer A | — | 2 |
| Example 23 | A | 30 | B | Image recording layer B | — | 2 |
| Example 24 | D | 30 | A | Image recording layer C | Protective layer A | 2 |
| Example 25 | D | 30 | A | Image recording layer C | Protective layer A | 1 |
| Example 26 | D | 30 | A | Image recording layer C | Protective layer A | 3 |
| Example 27 | D | 30 | A | Image recording layer C | Protective layer A | 4 |
| Example 28 | D | 30 | A | Image recording layer C | Protective layer A | 5 |
| Example 29 | D | 30 | A | Image recording layer C | Protective layer A | 6 |
| Example 30 | D | 30 | A | Non-photosensitive layer D | Protective layer A | 7 |
| Example 31 | D | 30 | A | Non-photosensitive layer D | Protective layer A | 8 |
| Example 32 | D | 30 | C | Image recording layer E | Protective layer B | 2 |
| Example 33 | D | 30 | C | Image recording layer E | Protective layer B | 6 |
| Example 34 | A | 30 | A | Image recording layer A | — | 2 |
| Comparative | A | 7 | A | Image recording layer A | — | 2 |
| Example 1 | | | | | | |
| Comparative | A | 120 | A | Image recording layer A | — | 2 |
| Example 2 | | | | | | |
| Comparative | A | 30 | A | Image recording layer A | — | 2 |
| Example 3 | | | | | | |

| | End portion | | | | Evaluation | | | |
|---|---|---|---|---|---|---|---|---|
| | treatment | | | | | | | Deinking |
| | | Difference | Sagging | Sagging | Edge | Stain in | | capability |
| | Treatment | in content | amount | width | stain | setter and | Printing | after being left |
| | liquid | (mg/m²) | (μm) | (μm) | resistance | vendor | durability | to stand |
| Example 1 | A | 400 | 60 | 150 | 3 | Not found | 77 | 4 |
| Example 2 | A | 400 | 60 | 150 | 3 | Not found | 84 | 4 |
| Example 3 | A | 400 | 60 | 150 | 4 | Not found | 92 | 4 |
| Example 4 | A | 400 | 60 | 150 | 4 | Not found | 96 | 4 |
| Example 5 | A | 400 | 60 | 150 | 4 | Not found | 100 | 4 |
| Example 6 | A | 400 | 60 | 150 | 4 | Not found | 99 | 4 |
| Example 7 | A | 400 | 60 | 150 | 4 | Not found | 93 | 4 |
| Example 8 | A | 400 | 60 | 150 | 5 | Not found | 82 | 4 |
| Example 9 | A | 400 | 60 | 150 | 5 | Not found | 80 | 3 |
| Example 10 | A | 400 | 60 | 150 | 5 | Not found | 70 | 3 |
| Example 11 | A | 600 | 60 | 150 | 4 | Not found | 100 | 4 |
| Example 12 | A | 800 | 60 | 150 | 5 | Not found | 100 | 4 |
| Example 13 | A | 300 | 60 | 150 | 4 | Not found | 100 | 4 |
| Example 14 | A | 400 | 60 | 150 | 4 | Not found | 100 | 4 |
| Example 15 | A | 400 | 60 | 150 | 4 | Not found | 100 | 4 |
| Example 16 | A | 400 | 60 | 150 | 4 | Not found | 100 | 4 |
| Example 17 | A | 400 | 60 | 150 | 4 | Not found | 100 | 4 |
| Example 18 | A | 400 | 60 | 150 | 4 | Not found | 100 | 4 |
| Example 19 | B | 500 | 60 | 150 | 3 | Not found | 100 | 4 |
| Example 20 | C | 500 | 60 | 150 | 3 | Not found | 100 | 4 |
| Example 21 | A | 400 | 60 | 150 | 4 | Not found | 105 | 4 |
| Example 22 | A | 400 | 60 | 150 | 4 | Not found | 104 | 4 |
| Example 23 | A | 400 | 60 | 150 | 4 | Not found | 70 | 3 |
| Example 24 | A | 400 | 60 | 150 | 4 | Not found | 120 | 5 |
| Example 25 | A | 400 | 60 | 150 | 4 | Not found | 120 | 5 |
| Example 26 | A | 400 | 60 | 150 | 4 | Not found | 120 | 5 |
| Example 27 | A | 400 | 60 | 150 | 4 | Not found | 120 | 5 |
| Example 28 | A | 400 | 60 | 150 | 4 | Not found | 120 | 5 |
| Example 29 | A | 400 | 60 | 150 | 4 | Not found | 120 | 5 |
| Example 30 | A | 400 | 60 | 150 | 4 | Not found | — | 5 |
| Example 31 | A | 400 | 60 | 150 | 4 | Not found | — | 5 |
| Example 32 | A | 400 | 60 | 150 | 3 | Not found | 130 | 5 |
| Example 33 | A | 400 | 60 | 150 | 5 | Not found | 130 | 5 |
| Example 34 | A | 2200 | 60 | 150 | 5 | Found | 100 | 4 |
| Comparative | A | 400 | 60 | 150 | 2 | Not found | 65 | 5 |
| Example 1 | | | | | | | | |
| Comparative | A | 600 | 60 | 150 | 3 | Not found | 45 | 2 |
| Example 2 | | | | | | | | |
| Comparative | A | 5 | 60 | 150 | 1 | Not found | 100 | 4 |
| Example 3 | | | | | | | | |

As listed in Table 2, desired effects were obtained using the printing plate precursor according to the embodiment of the present invention.

In comparison of Examples 1 to 10, the balance between the edge stain resistance and the printing durability was excellent in a case where the average diameter was in a range of 15 to 80 nm (preferably in a range of 20 to 50 nm and more preferably in a range of 25 to 40 nm).

In comparison of Examples 5 and 11 to 13, the edge stain resistance was further excellent in a case where the difference in content was 700 mg/m² or greater.

In comparison of Examples 17, 19, and 20, the edge stain resistance was excellent in a case where the hydrophilizing agent contained at least one selected from the group consisting of a phosphoric acid compound and a phosphonic acid compound.

In comparison of Examples 5, 21, and 22, the printing durability was further excellent in a case where the shape of the micropores in the anodized film had a predetermined structure.

In comparison of Examples 12 and 34, the stains in the setter and the vendor were further suppressed in a case where the difference in content was 2000 mg/m² or less.

### EXPLANATION OF REFERENCES

1, 18: aluminum plate
2, 4: roller-like brushes
3: polishing slurry liquid
5, 6, 7, 8: support roller
ta: anodic reaction time
tc: cathodic reaction time
tp: time until current value reaches peak from zero
Ia: peak current on anode cycle side
Ic: peak current on cathode cycle side
10a, 10b, 10c: printing plate precursor
12a, 12b: aluminum support
14: undercoat layer
16: image recording layer
20a, 20b: anodized film
22a, 22b: micropore
24: large-diameter pore
26: small-diameter pore
30: sagging shape
32: end surface
34: surface of functional layer
40, 42: cutting blade
40a, 40b: upper cutting blade
42a, 42b: lower cutting blade
44, 46: rotating shaft
50: main electrolytic cell
51: AC power source
52: radial drum roller
53a, 53b: main pole
54: electrolytic solution supply port
55: electrolytic solution
56: auxiliary anode
60: auxiliary anode cell
W: aluminum plate
610: anodization treatment device
612: power supply tank
614: electrolytic treatment tank
616: aluminum plate
618, 626: electrolytic solution
620: power supply electrode
622, 628: roller
624: nip roller
630: electrolytic electrode
632: tank wall
634: DC power source

What is claimed is:

1. A printing plate precursor comprising:
an aluminum support; and
a functional layer which is disposed on the aluminum support and selected from the group consisting of an image recording layer and a non-photosensitive layer,
wherein the aluminum support includes an aluminum plate and an aluminum anodized film disposed on the aluminum plate,
the anodized film is positioned closer to the functional layer than the aluminum plate is,
the anodized film has micropores extending in a depth direction from a surface of the functional layer side, and
an average diameter of the micropores in the surface of the anodized film is in a range of 15 nm to 80 nm,
the printing plate precursor contains a hydrophilizing agent in a region on a plate surface of the functional layer side which extends to a distance of 5 mm inward from two facing end portions of the printing plate precursor, and
a content of the hydrophilizing agent per unit area in the region is greater than a content of the hydrophilizing agent per unit area in a region other than the region by 10 mg/m² or greater.

2. The printing plate precursor according to claim 1,
wherein the content of the hydrophilizing agent per unit area in the region is greater than the content of the hydrophilizing agent per unit area in a region other than the region by 10 to 2000 mg/m² or greater.

3. The printing plate precursor according to claim 1,
wherein the end portion of the printing plate precursor has a sagging shape with a sagging amount of 25 to 150 μm and a sagging width of 70 to 300 μm.

4. The printing plate precursor according to claim 1,
wherein the average diameter of the micropores in the surface of the anodized film is in a range of 13 to 30 nm, and
a maximum diameter inside the micropore is in a range of 40 to 300 nm.

5. The printing plate precursor according to claim 1,
wherein the micropores are formed of large-diameter pores extending to a position at a depth of 10 nm to 1000 nm from the surface of the anodized film and small-diameter pores communicating with a bottom of the large-diameter pores and extending to a position at a depth of 20 nm to 2000 nm from a communication position,
an average diameter of the large-diameter pores in the surface of the anodized film is in a range of 15 nm to 80 nm, and
an average diameter of the small-diameter pores in the communication position is 13 nm or less.

6. The printing plate precursor according to claim 1,
wherein the hydrophilizing agent is a water-soluble compound.

7. The printing plate precursor according to claim 1,
wherein the hydrophilizing agent contains at least one selected from the group consisting of a phosphoric acid compound and a phosphonic acid compound.

8. The printing plate precursor according to claim 7,
wherein the phosphoric acid compound and the phosphonic acid compound are polymer compounds.

9. The printing plate precursor according to claim 1,
wherein the hydrophilizing agent contains a water-soluble resin.

10. The printing plate precursor according to claim 1,
wherein the hydrophilizing agent contains an anionic surfactant or a non-ionic surfactant.

11. The printing plate precursor according to claim 1,
wherein the functional layer is an image recording layer which contains an infrared absorbing agent, a polymerization initiator, a polymerizable compound, and a polymer compound.

12. The printing plate precursor according to claim 11,
wherein the polymer compound contained in the image recording layer has a hydrophobic main chain and both a repeating unit which contains a pendant-cyano group directly bonded to the hydrophobic main chain and a repeating unit which contains a pendant group having a hydrophilic polyalkylene oxide segment.

13. The printing plate precursor according to claim 1,
wherein the functional layer is an image recording layer which contains an infrared absorbing agent and thermoplastic polymer particles.

14. A method of producing a printing plate, comprising:
an exposure step of imagewise-exposing the printing plate precursor according to claim 11 to form an exposed portion and an unexposed portion; and
a removal step of removing the unexposed portion of the imagewise-exposed printing plate precursor.

15. A printing method comprising:
an exposure step of imagewise-exposing the printing plate precursor according to claim 11 to form an exposed portion and an unexposed portion; and
a printing step of supplying at least any of printing ink or dampening water and removing the unexposed portion of the imagewise-exposed printing plate precursor on a printing press to perform printing.

16. The printing plate precursor according to claim 2,
wherein the end portion of the printing plate precursor has a sagging shape with a sagging amount of 25 to 150 μm and a sagging width of 70 to 300 μm.

17. The printing plate precursor according to claim 2,
wherein the average diameter of the micropores in the surface of the anodized film is in a range of 13 to 30 nm, and
a maximum diameter inside the micropore is in a range of 40 to 300 nm.

18. The printing plate precursor according to claim 3,
wherein the average diameter of the micropores in the surface of the anodized film is in a range of 13 to 30 nm, and
a maximum diameter inside the micropore is in a range of 40 to 300 nm.

19. The printing plate precursor according to claim 2,
wherein the micropores are formed of large-diameter pores extending to a position at a depth of 10 nm to 1000 nm from the surface of the anodized film and small-diameter pores communicating with a bottom of the large-diameter pores and extending to a position at a depth of 20 nm to 2000 nm from a communication position,
an average diameter of the large-diameter pores in the surface of the anodized film is in a range of 15 nm to 80 nm, and
an average diameter of the small-diameter pores in the communication position is 13 nm or less.

20. The printing plate precursor according to claim 3,
wherein the micropores are formed of large-diameter pores extending to a position at a depth of 10 nm to 1000 nm from the surface of the anodized film and small-diameter pores communicating with a bottom of the large-diameter pores and extending to a position at a depth of 20 nm to 2000 nm from a communication position,
an average diameter of the large-diameter pores in the surface of the anodized film is in a range of 15 nm to 80 nm, and
an average diameter of the small-diameter pores in the communication position is 13 nm or less.
